(19) United States
(12) Patent Application Publication
(10) Pub. No.: US 2026/0206223 A1
(43) Pub. Date: Jul. 16, 2026

(54) SEMICONDUCTOR MEMORY DEVICE, METHOD FOR FABRICATING THE SAME AND ELECTRONIC SYSTEM INCLUDING THE SAME

(71) Applicant: Samsung Electronics Co., Ltd., Suwon-si (KR)

(72) Inventor: Young Woo Kim, Suwon-si (KR)

(21) Appl. No.: 19/263,359

(22) Filed: Jul. 8, 2025

(30) Foreign Application Priority Data
Jan. 10, 2025 (KR) 10-2025-0004038

(51) Int. Cl. H10B 43/27; H10B 43/10; H10B 43/40

(52) U.S. Cl. CPC H10B 43/27; H10B 43/10; H10B 43/40

(57) ABSTRACT

A semiconductor memory device includes a stacked structure comprising a plurality of gate electrodes spaced apart from each other in a first direction and stacked in the first direction, a channel structure extending in the first direction, wherein the channel structure extends through the plurality of gate electrodes, a dam pattern surrounding at least a portion of the stacked structure in a plan view along the first direction, and an insulating liner extending along at least a portion of a side surface of the dam pattern and along a lower surface of the dam pattern.

### CROSS-REFERENCE TO RELATED APPLICATION

This application claims priority under 35 U.S.C. § 119 from Korea Patent Application No. 10-2025-0004038, filed on Jan. 10, 2025, in the Korea Intellectual Property Office, the contents of which are herein incorporated by reference in their entirety.

### BACKGROUND

As semiconductor memory devices capable of storing high capacity of data are required for electronic systems, ways capable of increasing the data storage capacity of the semiconductor memory devices are being researched. As one way for increasing the data storage capacity of the semiconductor memory devices, a semiconductor memory device including memory cells arranged three-dimensionally instead of memory cells arranged two-dimensionally has been proposed.

### SUMMARY

Some aspects of the present disclosure provide semiconductor memory devices having improved reliability, yield, and the like. Some aspects of the present disclosure provide methods for fabricating the semiconductor memory devices and electronic systems including the semiconductor memory devices.

According to some implementations of the present disclosure, there is provided a semiconductor memory device comprising a stacked structure comprising a plurality of gate electrodes spaced apart from each other in a first direction and stacked in the first direction, a channel structure extending in the first direction, wherein the channel structure extends through the plurality of gate electrodes, a dam pattern surrounding at least a portion of the stacked structure in a plan view along the first direction, and an insulating liner extending along at least a portion of a side surface of the dam pattern and along a lower surface of the dam pattern.

According to some implementations of the present disclosure, there is provided a semiconductor memory device comprising a stacked structure comprising a plurality of gate electrodes spaced apart from each other in a first direction and stacked in the first direction, a channel structure extending in the first direction, wherein the channel structure extends through and intersects the plurality of gate electrodes, a first conductive structure on an upper surface of the stacked structure, a second conductive structure on a lower surface of the stacked structure, a through via pattern extending in the first direction, wherein the through via pattern electrically connects the first conductive structure and the second conductive structure, a dam pattern surrounding at least a portion of a side surface of the stacked structure, wherein the dam pattern is vertically between the first conductive structure and the second conductive structure, and an insulating liner extending along at least a portion of the dam pattern, wherein the insulating liner separates the second conductive structure from the dam pattern.

According to some implementations of the present disclosure, there is provided a method for fabricating a semiconductor memory device, the method comprising forming a stacked structure, wherein the stacked structure includes a plurality of gate electrodes spaced apart from each other in a first direction and stacked in the first direction, forming a channel structure that extends in the first direction, wherein the channel structure extends through the plurality of gate electrodes, forming a first insulating film that covers the stacked structure and the channel structure, forming a through via hole and a dam hole, wherein the through via hole and the dam hole extend in the first direction, and wherein the through via hole and the dam hole extend through the first insulating film, forming an insulating liner and a sacrificial film in each of the through via hole and the dam hole, forming a second insulating film that covers the first insulating film, the insulating liner, and the sacrificial film, forming a first stud hole that extends through the second insulating film and exposes the sacrificial film in the through via hole, removing the insulating liner and the sacrificial film in the through via hole, by etching through the first stud hole, after removing the insulating liner and the sacrificial film in the through via hole, forming a second stud hole that extends through the second insulating film and exposes the sacrificial film in the dam hole, removing the sacrificial film in the dam hole, by etching through the second stud hole, and forming a conductive film in the through via hole and the dam hole.

According to some implementations of the present disclosure, there is provided an electronic system comprising a main board, a semiconductor memory device on the main board, and a controller on the main board, wherein the controller is electrically connected to the semiconductor memory device, wherein the semiconductor memory device includes, a stacked structure comprising a plurality of gate electrodes spaced apart from each other in a first direction and stacked in the first direction, a channel structure extending in the first direction, wherein the channel structure extends through the plurality of gate electrodes, a dam pattern surrounding at least a portion of the stacked structure in a plan view along the first direction, and an insulating liner extending along at least portion of a side surface of the dam pattern and along a lower surface of the dam pattern.

However, aspects of the present disclosure are not restricted to those set forth above. The above and other aspects of the present disclosure will become more apparent to one of ordinary skill in the art to which the present disclosure pertains by referencing the detailed description given below.

### BRIEF DESCRIPTION OF THE DRAWINGS

FIG. 1 is a block diagram illustrating an example of a semiconductor memory device.

FIG. 2 is a circuit diagram illustrating an example of a semiconductor memory device.

FIG. 3 is a schematic layout diagram illustrating an example of a semiconductor memory device.

FIG. 4 is a schematic cross-sectional view taken along a line A-A of FIG. 3.

FIG. 5 is an enlarged view of region R1 of FIG. 4.

FIGS. 6A to 6F are enlarged views illustrating examples of a region R2a and a region R2b of FIG. 4.

FIG. 7 is another schematic cross-sectional view taken along A-A of FIG. 3.

FIG. 8 is an enlarged view illustrating a region R3 of FIG. 7.

FIG. 9 is another schematic cross-sectional view taken along A-A of FIG. 3

FIG. 10 is an enlarged view illustrating a region R4 of FIG. 9.

FIGS. 11 to 25 are diagrams illustrating an example of a method of fabricating a semiconductor memory device.

FIG. 26 is a block diagram illustrating an example of an electronic system.

FIG. 27 is a perspective view illustrating an example of an electronic system.

FIG. 28 is a schematic cross-sectional view taken along I-I of FIG. 27

### DETAILED DESCRIPTION

It will be understood that, although the terms “first”, “second”, and so on may be used herein to describe various elements and/or components, these terms are used to distinguish one element or component from another element or component, without implying any ordering thereof. Thus, a first element or component described below could be termed a second element or component without departing from the spirit and scope of the present disclosure.

Moreover, as used herein, the term “same” is not limited to elements that are completely identical but also includes elements having small differences that may occur due to a margin in a process, etc.

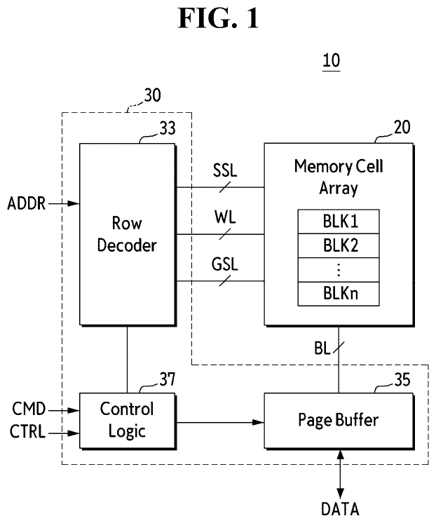

Hereinafter, semiconductor memory devices will be described referring to FIGS. 1 to 10.

FIG. 1 is a block diagram illustrating an example of a semiconductor memory device. A memory cell array 20 may include a plurality of memory cell blocks BLK1 to BLKn. Each of the memory cell blocks BLK1 to BLKn may include a plurality of memory cells. The memory cell array 20 may be connected to a peripheral circuit 30 through a bit line BL, a word line WL, at least one string selection line SSL, and at least one ground selection line GSL. Specifically, the memory cell blocks BLK1 to BLKn may be connected to a row decoder 33 through the word line WL, the string selection line SSL, and the ground selection line GSL. Further, the memory cell blocks BLK1 to BLKn may be connected to a page buffer 35 through the bit line BL.

The peripheral circuit 30 may receive an address ADDR, a command CMD, and a control signal CTRL from the outside of the semiconductor memory device 10, and may transmit and receive data DATA to and from an external device of the semiconductor memory device 10. The peripheral circuit 30 may include the row decoder 33, the page buffer 35 and a control logic 37. The peripheral circuit 30 may further include various sub-circuits such as an input/output circuit, a voltage generation circuit that generates various voltages necessary for the operation of the semiconductor memory device 10, and an error correction circuit for correcting an error of the data DATA that is read from the memory cell array 20.

The control logic 37 may be connected to the row decoder 33, the page buffer 35, the input/output circuit, the voltage generation circuit and the like. The control logic 37 may control the overall operation of the semiconductor memory device 10. The control logic 37 may generate various internal control signals used inside the semiconductor memory device 10 in response to the control signal CTRL. For example, the control logic 37 may adjust the voltage levels provided to the word lines WL and the bit lines BL, when performing a memory operation such as a program operation or an erasing operation.

The row decoder 33 may select at least one of the plurality of memory cell blocks BLK1 to BLKn in response to the address ADDR, and may select at least one word line WL, at least one string selection line SSL, and at least one ground selection line GSL of the selected memory cell blocks BLK1 to BLKn. Further, the row decoder 33 may transfer a voltage for performing the memory operation to the word line WL of the selected memory cell blocks BLK1 to BLKn.

The page buffer 35 may be connected to the memory cell array 20 through the bit lines BL. The page buffer 35 may operate as a writer driver or a sense amplifier. Specifically, when performing the program operation, the page buffer 35 may operate as the writer driver to apply a voltage according to the data DATA to be stored in the memory cell array 20 to the bit line BL. On the other hand, when performing the read operation, the page buffer 35 may operate as a sense amplifier to sense the data DATA stored in the memory cell array 20.

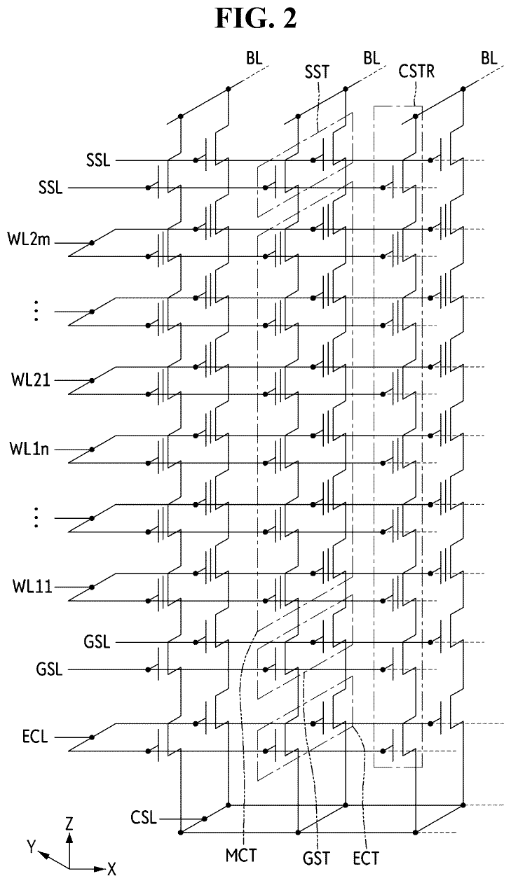

FIG. 2 is a circuit diagram illustrating an example of a semiconductor memory device.

Referring to FIG. 2, a memory cell array (e.g., 20 of FIG. 1) of the semiconductor device may include a plurality of cell strings CSTR. Each of the plurality of cell strings CSTR may extend in a first direction Z, and may be arranged two-dimensionally in a plane (e.g., an XY plane including a second direction X and a third direction Y) that intersects the first direction Z. The second and third directions X and Y may be lateral directions that are perpendicular to the first direction Z. The first direction Z may be a vertical direction, and the second and third directions X and Y may be lateral directions.

The plurality of cell strings CSTR may be connected between a plurality of bit lines BL and a common source line CSL. The bit lines BL may be spaced apart from each other in the second direction X and each extend long in the third direction Y. A plurality of cell strings CSTR may be connected in parallel to each bit line BL. The plurality of cell strings CSTR may be commonly connected to the common source line CSL.

Each cell string CSTR may include a ground selection transistor GST connected to the common source line CSL, a string selection transistor SST connected to the bit line BL, and a plurality of memory cell transistors MCT connected between the ground selection transistor GST and the string selection transistor SST. Each memory cell transistor MCT may include a data storage element. The ground selection transistor GST, the string selection transistor SST, and the memory cell transistors MCT may be connected in series along the first direction Z.

The common source line CSL may be commonly connected to the sources of the ground selection transistors GST. In addition, the ground selection line GSL, a plurality of word lines WL11 to WL1n, WL21 to WL2m, and the string selection line SSL may be disposed between the common source line CSL and the bit line BL. The ground selection line GSL may be used as a gate electrode of the ground selection transistor GST, the word lines WL11 to WL1n, WL21 to WL2m may be used as gate electrodes of the memory cell transistor MCT, and the string selection line SSL may be used as a gate electrode of the string selection transistor SST.

In some implementations, an erasing control transistor ECT may be disposed between the common source line CSL and the ground selection transistor GST. The common source line CSL may be commonly connected to the sources of the erasing control transistors ECT. Further, an erasing control line ECL may be disposed between the common source line CSL and the ground selection line GSL. The erasing control line ECL may be used as a gate electrode of the erasing control transistor ECT. The erasing control transistors ECT may perform the erasing operation of the memory cell array, using a gate induced drain leakage (GIDL).

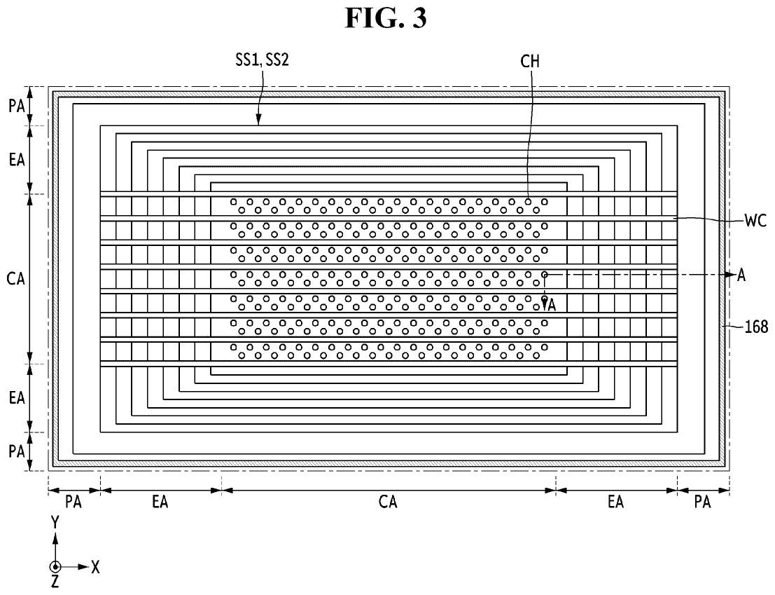

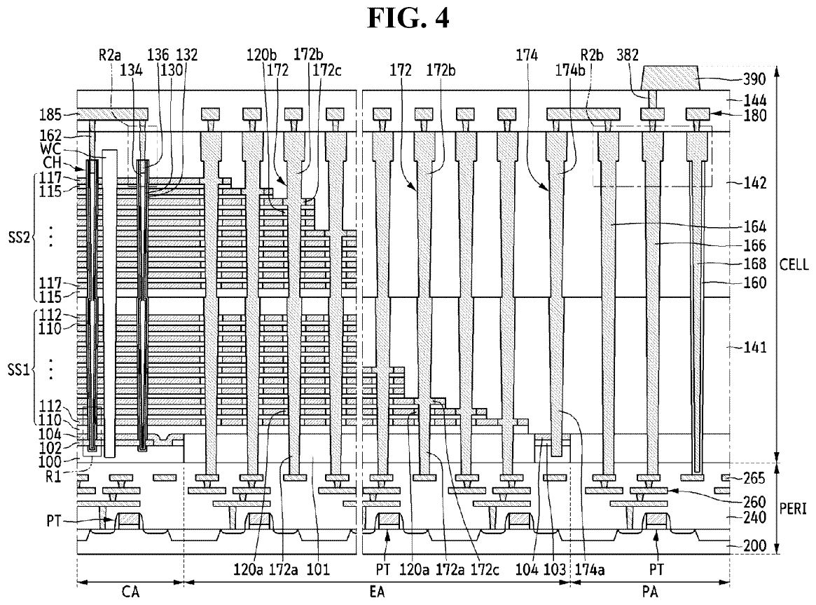

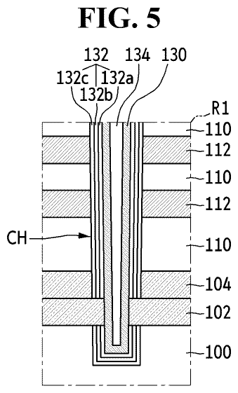

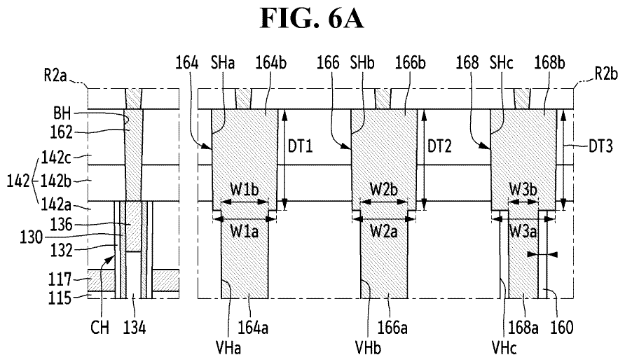

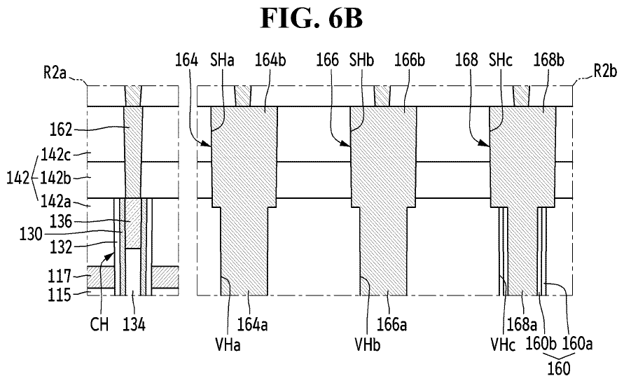

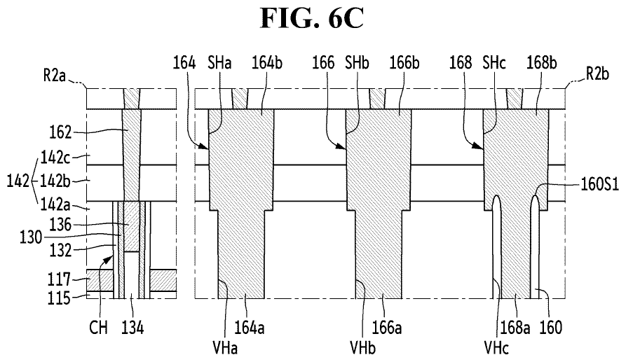

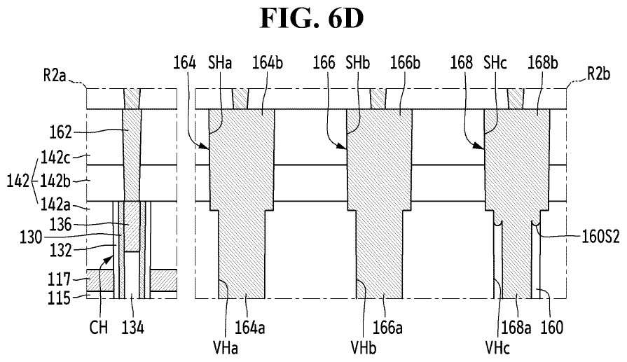

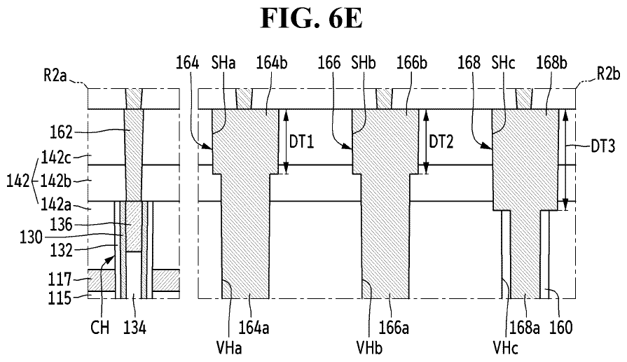

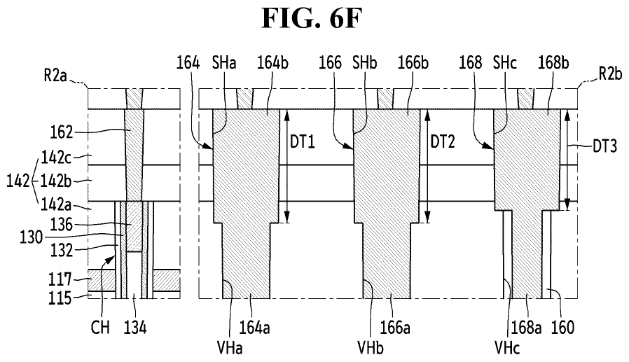

FIG. 3 is a schematic layout diagram illustrating an example of a semiconductor memory device. FIG. 4 is a schematic cross-sectional view taken along line A-A of FIG. 3. FIG. 5 is an enlarged view illustrating a region R1 of FIG. 4. FIGS. 6A to 6F are enlarged views illustrating a region R2a and a region R2b of FIG. 4.

Referring to FIGS. 1 to 6A, the semiconductor memory device includes a memory cell structure CELL and a peripheral circuit structure PERI.

The memory cell structure CELL may include a first substrate 100, an insulating substrate 101, a first stacked structure SS1, a first interlayer insulating film 141, a second stacked structure SS2, a second interlayer insulating film 142, a channel structure CH, a source layer 102, a source sacrificial layer 103, a support layer 104, a cut pattern WC, a gate contact 172, a source contact 174, a channel stud pattern 162, a first through via pattern 164, a second through via pattern 166, a dam pattern 168, an insulating liner 160, a first conductive structure 180, and a conductive pad 390.

The first substrate 100 may include, for example, a semiconductor substrate such as a silicon substrate, a germanium substrate or a silicon-germanium substrate. The first substrate 100 may include a silicon-on-insulator (SOI) substrate, a germanium-on-insulator (GOI) substrate, or the like.

The first substrate 100 may include a cell array region CA, an extension region EA, and an external region PA.

A memory cell array (e.g., 20 of FIG. 1) including a plurality of memory cells may be formed on the cell array region CA. For example, a source layer 102, a channel structure CH, gate electrodes 112 and 117, a conductive line 185, and the like, which will be described below, may be disposed on the cell array region CA. In the following description, a surface (e.g., an upper surface) of the first substrate 100 on which the memory cell array is disposed may also be referred to as a front side of the first substrate 100. Conversely, a surface (e.g., a lower surface) of the first substrate 100 opposite to the front side of the first substrate 100 may also be referred to as a back side of the first substrate 100.

The extension region EA may be disposed around the cell array region CA. For example, the extension region EA may be adjacent to the cell array region CA in the second direction X. Gate electrodes 112 and 117, which will be described below, may be stacked on the extension region EA in a stepped manner.

The external region PA may be a peripheral region that surrounds the cell array region CA and the extension region EA. For example, the external region PA may be adjacent to the cell array region CA and/or the extension region EA in the second direction X and/or the third direction Y. A first through via pattern 164, a second through via pattern 166, a dam pattern 168, a conductive pad 390, and the like, which will be described below, may be disposed on the external region PA.

The insulating substrate 101 may form an insulating region inside the extension region EA of the first substrate 100 and/or the external region PA of the first substrate 100. The insulating substrate 101 may include, for example, but is not limited to, at least one of silicon oxide, silicon nitride, silicon oxynitride, or silicon carbide.

The first stacked structure SS1 may be formed on the front side of the first substrate 100. The first stacked structure SS1 may be stacked on the first substrate 100 and/or the insulating substrate 101. The first stacked structure SS1 may include a plurality of first mold insulating films 110 and a plurality of first gate electrodes 112 that are alternately stacked along the first direction Z. Each of the first mold insulating films 110 and each of the first gate electrodes 112 may have a layered structure extending along a horizontal plane (e.g., an XY plane). The first gate electrodes 112 may be spaced apart from each other by the first mold insulating films 110, and be stacked in sequence.

In some implementations, the first gate electrodes 112 may include at least one erasing control line (e.g., ECL of FIG. 2), at least one ground selection line (e.g., GSL of FIG. 2), and a plurality of first word lines (e.g., WL11 to WL1n of FIG. 2) that are stacked sequentially on the first substrate 100. The number, thickness and the like of the first mold insulating film 110 and the first gate electrodes 112 are merely examples, and the scope of this disclosure is not limited to those shown.

Each of the first gate electrodes 112 on the cell array region CA may further extend onto the extension region EA. The first gate electrodes 112 on the extension region EA may be stacked in a stepped manner. For example, on the extension region EA, the length of the first gate electrodes 112 extending in the second direction X may decrease as they go away from the first substrate 100 and/or the insulating substrate 101.

The first interlayer insulating film 141 may cover the first stacked structure SS1. The first interlayer insulating film 141 may include, but is not limited to, at least one of silicon oxide, silicon oxynitride, and/or a low dielectric constant (low-k) material having a dielectric constant smaller than that of silicon oxide.

The second stacked structure SS2 may be stacked on the first stacked structure SS1 and the first interlayer insulating film 141. The second stacked structure SS2 may include a plurality of second mold insulating films 115 and a plurality of second gate electrodes 117 that are stacked alternately along the first direction Z. Each of the second mold insulating films 115 and each of the second gate electrodes 117 may have a layered structure extending along the horizontal plane (e.g., the XY plane). The second gate electrodes 117 may be spaced apart from each other by the second mold insulating film 115, and be stacked in sequence.

In some implementations, the second gate electrodes 117 may include a plurality of second word lines (e.g., WL21 to WL2m of FIG. 2) and at least one string selection line (e.g., SSL of FIG. 2) that are stacked on the first stacked structure SS1 in sequence. The number, thickness and the like of the second mold insulating films 115 and the second gate electrodes 117 are examples. and the scope of this disclosure is not limited to those shown in the drawings.

Each second gate electrode 117 on the cell array region CA may extend further onto the extension region EA. The second gate electrodes 117 on the extension region EA may be stacked in a stepped manner. For example, the length of the second gate electrodes 117 extending in the second direction X on the extension region EA may decrease as they go away from the first substrate 100 and/or the insulating substrate 101.

The second interlayer insulating film 142 may cover the second stacked structure SS2. The second interlayer insulating film 142 may include, but is not limited to, at least one of silicon oxide, silicon oxynitride, and/or a low dielectric constant (low-k) material having a dielectric constant smaller than that of silicon oxide.

Each of the gate electrodes 112 and 117 may include a conductive material, for example, but are not limited to, a metal such as tungsten (W), molybdenum (Mo), ruthenium (Ru), cobalt (Co) and nickel (Ni), or a semiconductor material such as silicon. In some implementations, each of the gate electrodes 112 and 117 may include a metal film. As an example, each of the gate electrodes 112 and 117 may include at least one of a tungsten (W) film, a molybdenum (Mo) film, and/or a ruthenium (Ru) film.

Each of the mold insulating films 110 and 115 may include, for example, but are not limited to, at least one of silicon oxide, silicon nitride, and/or silicon oxynitride. As an example, each of the mold insulating films 110 and 115 may include a silicon oxide film.

The channel structure CH may be formed on the cell array region CA of the first substrate 100. The plurality of channel structures CH may each extend in the first direction Z and penetrate the stacked structures SS1 and SS2. As an example, the channel structure CH may be a pillar-shaped (e.g., cylindrical) structure extending in the first direction Z. Thus, the channel structure CH may intersect a plurality of gate electrodes 112 and 117.

In some implementations, each channel structure CH may have a step between the first stacked structure SS1 and the second stacked structure SS2. For example, as shown in FIG. 4, the side surfaces of each channel structure CH may have a bending portion at a boundary between the first interlayer insulating film 141 and the second stacked structure SS2.

Each channel structure CH may include a semiconductor film 130 and a data storage film 132.

The semiconductor film 130 may extend in the first direction Z and intersect the plurality of gate electrodes 112 and 117. Although the semiconductor film 130 is shown as being a cup-like shape, this is merely an example. For example, the semiconductor film 130 may have various shapes such as a cylindrical shape, a rectangular barrel shape, and a solid filler shape. The semiconductor film 130 may include, for example, but is not limited to, semiconductor materials such as single crystal silicon, polycrystalline silicon, organic semiconductor material, and carbon nanostructure.

The data storage film 132 may be interposed between the semiconductor film 130 and each of the gate electrodes 112 and 117. For example, the data storage film 132 may extend along the outer side surface of the semiconductor film 130. The data storage film 132 may include, for example, but is not limited to, at least one of silicon oxide, silicon nitride, silicon oxynitride, or high dielectric constant materials having a higher dielectric constant than silicon oxide. The high dielectric constant materials may include, for example, at least one of aluminum oxide, hafnium oxide, lanthanum oxide, tantalum oxide, titanium oxide, lanthanum hafnium oxide, lanthanum aluminum oxide, dysprosium scandium oxide, and/or combinations thereof.

In some implementations, the data storage film 132 may be formed of multiple films. For example, as shown in FIG. 5, the data storage film 132 may include a tunnel insulating film 132a, a charge storage film 132b, and a blocking insulating film 132c that are stacked sequentially on the outer side surface of the semiconductor film 130.

The tunnel insulating film 152a may include, for example, silicon oxide or a high dielectric constant material having a higher dielectric constant than silicon oxide (for example, aluminum oxide (Al₂O₃), and hafnium oxide (HfO₂)). The charge storage film 132b may include, for example, silicon nitride. The blocking insulating film 132c may include, for example, silicon oxide or a high dielectric constant material having a higher dielectric constant than silicon oxide (for example, aluminum oxide (Al₂O₃), and hafnium oxide (HfO₂)).

In some implementations, each channel structure CH may further include a filling insulating film 134. The filling insulating film 134 may be formed to fill the inside of the cup-shaped semiconductor film 130. The filling insulating film 134 may include, for example, but is not limited to, at least one of silicon oxide, silicon nitride, and/or silicon oxynitride.

In some implementations, each channel structure CH may further include a channel pad 136. The channel pad 136 may be connected to one end (e.g., an upper end) of the semiconductor film 130. The channel pad 136 may include a conductive material, for example, impurity-doped polysilicon, a metal, a metal silicide or the like. As an example, the channel pad 136 may include polysilicon (polySi) doped with N-type impurities (e.g., phosphorus (P) or arsenic (As)).

The source layer 102 may be formed on the cell array region CA of the first substrate 100. The source layer 102 may be interposed between the first substrate 100 and the first stacked structure SS1. For example, the source layer 102 may extend conformally along the upper surface of the cell array region CA of the first substrate 100.

The source layer 102 may be connected to the semiconductor film 130 of each channel structure CH. For example, as shown in FIG. 5, the source layer 102 may penetrate the data storage film 132 and come into contact with the side surface of the semiconductor film 130. The source layer 102 may include a conductive material, for example, but is not limited to, impurity-doped polysilicon, a metal or the like. The source layer 102 may be provided as a common source line (e.g., CSL of FIG. 2) of the semiconductor memory device.

In some implementations, the channel structure CH may penetrate the source layer 102. For example, a lower portion of the channel structure CH may be connected to the first substrate 100 under the source layer 102.

In some implementations, a base insulating film may be interposed between the first substrate 100 and the source layer 102. The base insulating film may include, for example, but is not limited to, at least one of silicon oxide, silicon nitride, and silicon oxynitride.

In some implementations, the first substrate 100 may include a conductive film. The conductive film may include, for example, impurity-doped polysilicon, metal, metal silicide, or the like. The conductive film may be formed of multiple layers. As an example, the first substrate 100 may include a first conductive film including a metal silicide such as tungsten silicide (WSi), and a second conductive film stacked on the first conductive film and including doped polysilicon. The source layer 102 and the conductive film may be provided as a common source line (e.g., CSL of FIG. 2) of the semiconductor memory device.

The source sacrificial layer 103 may be formed on the extension region EA of the first substrate 100. The source sacrificial layer 103 may be interposed between the first substrate 100 and the first stacked structure SS1. For example, the source sacrificial layer 103 may extend conformally along the upper surface of the extension region EA of the first substrate 100.

The source sacrificial layer 103 may be disposed at the same level as the source layer 102. In this specification, the expression “disposed at the same level” means disposed at the same height with respect to the upper surface of the first substrate 100. For example, the lower surface of the source sacrificial layer 103 may be disposed at the same height as the lower surface of the source layer 102.

In some implementations, the source layer 102 and/or the source sacrificial layer 103 may not be formed on the insulating substrate 101. The upper surface of the insulating substrate 101 is shown as being disposed to be coplanar with the upper surface of the support layer 104, but this is merely an example. As another example, the upper surface of the insulating substrate 101 may be formed to be higher than the upper surface of the support layer 104.

The source sacrificial layer 103 may be a layer that remains after a part thereof is replaced by the source layer 102. In this case, the thickness of the source layer 102 may be the same as the thickness of the source sacrificial layer 103. For example, the upper surface of the source sacrificial layer 103 may be disposed at the same height as the upper surface of the source layer 102.

The source sacrificial layer 103 may include an insulating material, for example, but is not limited to, at least one of silicon oxide, silicon nitride, or silicon oxynitride. In some implementations, the source sacrificial layer 103 may include a material having an etching selectivity with respect to the mold insulating films 110 and 115. As an example, each of the mold insulating films 110 and 115 may include a silicon oxide film, and the source sacrificial layer 103 may include a silicon nitride film.

The support layer 104 may be formed on the first substrate 100, the source layer 102, and the source sacrificial layer 103. The support layer 104 may be interposed between the source layer 102 and the first stacked structure SS1, and between the source sacrificial layer 103 and the first stacked structure SS1. For example, the support layer 104 may extend conformally along the upper surface of the first substrate 100, the upper surface of the source layer 102, and the upper surface of the source sacrificial layer 103.

The support layer 104 may include a material having an etching selectivity with respect to the source sacrificial layer 103. As an example, the source sacrificial layer 103 may include a silicon nitride film, and the support layer 104 may include a polysilicon film.

The support layer 104 may be used as a support for preventing the mold stack from collapsing or falling in a replacement process for forming the source layer 102. For example, the source layer 102 and/or the source sacrificial layer 103 may expose a part of the upper surface of the first substrate 100, and a part of the support layer 104 may extend along the exposed upper surface of the first substrate 100 and come into contact with the upper surface of the first substrate 100.

The cut pattern WC may be formed on the cell array region CA and the extension region EA. The cut pattern WC may extend long in the second direction X and cut the stacked structures SS1 and SS2. The plurality of cut patterns WC may be spaced apart from each other in the third direction Y. The stacked structures SS1 and SS2 may be divided by the plurality of cut patterns WC and form a plurality of memory cell blocks (e.g., BLK1 to BLKn of FIG. 1). For example, two adjacent cut patterns WC may define one memory cell block therebetween. A plurality of channel structures CH may be disposed in each memory cell block defined by the cut patterns WC.

In some implementations, the cut patterns WC may include an insulating material, for example, but not limited to, at least one of silicon oxide, silicon nitride, and/or silicon oxynitride. As an example, the cut patterns WC may include a silicon oxide film.

The gate contact 172 may be formed on the extension region EA. The plurality of gate contacts 172 may be electrically connected to the corresponding plurality of gate electrodes 112 and 117. For example, each gate contact 172 may extend in the first direction Z, and be connected to a corresponding one pad region of the gate electrodes 112 and 117. Here, the pad region may refer to a part of each gate electrode 112 and 117 whose upper surface is exposed on the extension region EA.

The gate contact 172 may include, a conductive material, for example, but is not limited to, a metal such as tungsten (W), cobalt (Co) and nickel (Ni), or a semiconductor material such as silicon.

In the following description, a gate electrode electrically connected to a particular one gate contact 172 among the gate electrodes 112 and 117 may be referred to as a selected gate electrode, and gate electrodes other than the selected gate electrode SWL may be referred to as non-selected gate electrodes.

In some implementations, the gate contact 172 may extend in the first direction Z and penetrate the stacked structures SS1 and SS2 on the extension region EA. For example, each gate contact 172 may penetrate the pad region of the selected gate electrode and come into contact with an inner side surface of the pad region of the selected gate electrode. Each gate contact 172 may penetrate the non-selected gate electrode, and be spaced apart from the non-selected gate electrode. For example, a first insulating ring 120a may be formed in the first stacked structure SS1, and a second insulating ring 120b may be formed in the second stacked structure SS2. Each of the first insulating ring 120a and the second insulating ring 120b may be an annular structure that surrounds the side surface of the gate contact 172 inside the non-selected gate electrode. The gate contact 172 may be spaced apart from the non-selected gate electrode of the first stacked structure SS1 by the first insulating ring 120a, and may be spaced apart from the non-selected gate electrode of the second stacked structure SS2 by the second insulating ring 120b.

In some implementations, the gate contact 172 may have a step between the first stacked structure SS1 and the second stacked structure SS2. For example, the gate contact 172 may include a first through portion 172a and a second through portion 172b. The first through portion 172a may extend in the first direction Z, and penetrate the first stacked structure SS1. The second through portion 172b may extend in the first direction Z, and penetrate the second stacked structure SS2. At the boundary between the first interlayer insulating film 141 and the second stacked structure SS2, a width of the first penetrating portion 172a may be greater than a width of the second penetrating portion 172b. Accordingly, the side surface of the gate contact 172 may have a bending portion at the boundary between the first interlayer insulating film 141 and the second stacked structure SS2.

In some implementations, the gate contact 172 may include a protrusion 172c. The protrusion 172c may protrude from one side surface of the first through portion 172a and the second through portion 172b. The protrusion 172c may be formed inside a pad region of the selected gate electrode. The gate contact 172 may come into contact with the pad region of the selected gate electrode through the protrusion 172c.

The source contact 174 may be connected to the source layer 102. For example, the source contact 174 may extend in the first direction Z on the extension region EA. The source contact 174 may penetrate the first interlayer insulating film 141 and the second interlayer insulating film 142, and be connected to the source layer 102, the support layer 104, and/or the first substrate 100.

The source contact 174 may include, a conductive material, for example, but is not limited to, a metal such as tungsten (W), cobalt (Co) and nickel (Ni), or a semiconductor material such as silicon.

In some implementations, the gate contact 172 and the source contact 174 may be formed at the same level. In this specification, the expression “formed at the same level” means a configuration formed by the same fabrication process, e.g., the same lithography, etching, and/or deposition operation(s), and should not be confused with “disposed at the same level,” which refers to a physical arrangement as discussed above.

The channel stud pattern 162 may be formed on the cell array region CA. The channel stud pattern 162 may be connected to one end (e.g., the upper end) of the channel structure CH. For example, as shown in FIG. 6A, the second interlayer insulating film 142 may include a first insulating film 142a, a second insulating film 142b, and a third insulating film 142c that are stacked in sequence. The second insulating film 142b may cover the upper surface of the channel structure CH and the first insulating film 142a. The third insulating film 142c may cover the upper surface of the second insulating film 142b. In addition, a channel stud hole BH which extends in the first direction Z and exposes the upper surface of the channel pad 136 may be formed inside the second insulating film 142b and the third insulating film 142c. The channel stud pattern 162 may be formed inside the channel stud hole BH and come into contact with the upper surface of the channel pad 136.

Although FIG. 6A shows that there are interfaces between the first insulating film 142a, the second insulating film 142b, and the third insulating film 142c, this is an example, and in some implementations there may be no interface between the first insulating film 142a, the second insulating film 142b, and the third insulating film 142c.

The channel stud pattern 162 may include a conductive material, for example, but is not limited to, a metal such as tungsten (W), cobalt (Co) or nickel (Ni), or a semiconductor material such as silicon.

The first through via pattern 164 may be formed on the external region PA. The first through via pattern 164 may extend in the first direction Z, and penetrate the first interlayer insulating film 141 and the second interlayer insulating film 142. In the first direction Z, a length of the first through via pattern 164 may be greater than a length of the stacked structures SS1 and SS2. For example, the height of the upper surface of the first through via pattern 164 may be higher than the height of the upper surface of the second stacked structure SS2, and the height of the lower surface of the first through via pattern 164 may be lower than the height of the lower surface of the first stacked structure SS1.

In some implementations, the width of the first through via pattern 164 may decrease toward the peripheral circuit structure PERI. This may be due to the characteristics of the etching process for forming the first through via pattern 164.

The first through via pattern 164 may include a conductive material, for example, but is not limited to, a metal such as tungsten (W), cobalt (Co) and nickel (Ni), or a semiconductor material such as silicon.

The first through via pattern 164 may be formed on the cell array region CA and/or the extension region EA. The first through via pattern 164 on the cell array region CA and/or the extension region EA may extend in the first direction Z, and penetrate the stacked structures SS1 and SS2.

As shown in FIG. 6A, the first through via pattern 164 may include a first via pattern 164a, and a first stud pattern 164b on the first via pattern 164a. The first via pattern 164a may extend long in the first direction Z, and penetrate the first insulating film 142a. For example, a first via hole VHa that extends long in the first direction Z and penetrates the first insulating film 142a may be formed. The first via pattern 164a may fill at least a part of the first via hole VHa. The first stud pattern 164b may penetrate the second insulating film 142b and the third insulating film 142c, and be connected to the upper portion of the first via pattern 164a. For example, a first stud hole SHa that extends in the first direction Z and exposes the upper surface of the first via pattern 164a may be formed inside the second insulating film 142b and the third insulating film 142c. The first stud pattern 164b may be formed inside the first stud hole SHa and be connected to the first via pattern 164a. In some implementations, the first via pattern 164a and the first stud pattern 164b may be formed integrally at the same level.

In some implementations, the width of the first stud pattern 164b may be greater than the width of the first via pattern 164a. For example, in a plane including the lowermost surface of the first stud hole SHa, a width W1a of the first stud pattern 164b may be greater than a width W1b of the first via pattern 164a.

In some implementations, the height of the lowermost surface of the first stud pattern 164b may be lower than the height of the uppermost surface of the channel structure CH. For example, a depth DT1 at which the first stud pattern 164b is formed may be greater than the sum of the thicknesses of the second insulating film 142b and the third insulating film 142c, on the basis of the upper surface of the first stud pattern 164b.

The second through via pattern 166 may be formed on the external region PA. The second through via pattern 166 may be spaced apart from the first through via pattern 164. The second through via pattern 166 may extend in the first direction Z, and penetrate the first interlayer insulating film 141 and the second interlayer insulating film 142. In the first direction Z, the length of the second through via pattern 166 may be greater than the length of the stacked structures SS1 and SS2. For example, the height of the upper surface of the second through via pattern 166 may be higher than the height of the upper surface of the second stacked structure SS2, and the height of the lower surface of the second through via pattern 166 may be lower than the height of the lower surface of the first stacked structure SS1.

In some implementations, the width of the second through via pattern 166 may decrease toward the peripheral circuit structure PERI. This may be due to the characteristics of the etching process for forming the second through via pattern 166.

The second through via pattern 166 may include a conductive material, for example, but is not limited to, a metal such as tungsten (W), cobalt (Co) or nickel (Ni), or a semiconductor material such as silicon.

In some implementations, the first through via pattern 164 and the second through via pattern 166 may be formed at the same level as the channel stud pattern 162. For example, the first through via pattern 164 and the second through via pattern 166 may have the same material configuration (e.g., be composed of the same material(s)) as that of the channel stud pattern 162.

As shown in FIG. 6A, the second through via pattern 166 may include a second via pattern 166a, and a second stud pattern 166b on the second via pattern 166a. The second via pattern 166a may extend long in the first direction Z and penetrate the first insulating film 142a. For example, a second via hole VHb extending in the first direction Z and penetrating the first insulating film 142a may be formed. The second via pattern 166a may fill at least a part of the second via hole VHb. The second stud pattern 166b may penetrate the second insulating film 142b and the third insulating film 142c, and be connected to an upper portion of the second via pattern 166a. For example, a second stud hole SHb which extends in the first direction Z and exposes an upper surface of the second via pattern 166a may be formed inside the second insulating film 142b and the third insulating film 142c. The second stud pattern 166b may be formed inside the second stud hole SHb, and be connected to the second via pattern 166a. In some implementations, the second via pattern 166a and the second stud pattern 166b may be formed integrally at the same level.

In some implementations, the width of the second stud pattern 166b may be greater than the width of the second via pattern 166a. For example, in a plane including the lowermost surface of the second stud hole SHb, a width W2a of the second stud pattern 166b may be greater than a width W2b of the second via pattern 166a.

Although an example is shown in which the width W1b of the first via pattern 164a and the width W2b of the second via pattern 166a are equal to each other, and the width W1a of the first stud pattern 164b and the width W2a of the second stud pattern 166b are equal to each other, this is an example. In some implementations, the width W1b of the first via pattern 164a and the width W2b of the second via pattern 166a may be different from each other, and/or the width W1a of the first stud pattern 164b and the width W2a of the second stud pattern 166b may be different from each other.

In some implementations, the height of the lowermost surface of the second stud pattern 166b may be lower than the height of the uppermost surface of the channel structure CH. For example, a depth DT2 at which the second stud pattern 166b is formed may be greater than the sum of the thicknesses of the second insulating film 142b and the third insulating film 142c, on the basis of the upper surface of the second stud pattern 166b.

In some implementations, the depth DT1 of the first stud pattern 164b and a depth DT2 of the second stud pattern 166b may be equal to each other.

The dam pattern 168 may be formed on the external region PA. The dam pattern 168 may be spaced apart from the first through via pattern 164 and the second through via pattern 166. The dam pattern 168 may extend in the first direction Z and penetrate the first interlayer insulating film 141 and the second interlayer insulating film 142. In the first direction Z, the length of the dam pattern 168 may be greater than the length of the stacked structures SS1 and SS2. For example, the height of the upper surface of the dam pattern 168 may be higher than the height of the upper surface of the second stacked structure SS2 (e.g., higher than an uppermost one of the gate electrodes 117), and the height of the lower surface of the dam pattern 168 may be lower than the height of the lower surface of the first stacked structure SS1 (e.g., lower than a lowermost one of the gate electrodes 112).

The dam pattern 168 may surround at least a part of the side surfaces of the stacked structures SS1 and SS2. For example, as shown in FIG. 3, the dam pattern 168 may surround the stacked structures SS1 and SS2 from a planar point of view (or plan view) along the first direction Z (e.g., in the XY plane). Although the dam pattern 168 is shown as being a square frame shape from the planar point of view along the first direction Z (e.g., in the XY plane), this is an example, and it will be understood that the dam pattern 168 may have various other shapes that surround the stacked structures SS1 and SS2.

In some implementations, the first through via pattern 164 and/or the second through via pattern 166 may be interposed between the stacked structures SS1 and SS2 and the dam pattern 168.

In some implementations, the width of the dam pattern 168 may decrease toward the peripheral circuit structure PERI. This may be due to the characteristics of the etching process for forming the dam pattern 168.

The dam pattern 168 may include a conductive material, for example, but is not limited to, a metal such as tungsten (W), cobalt (Co) or nickel (Ni), or a semiconductor material such as silicon.

In some implementations, the dam pattern 168 may be formed at the same level as the channel stud pattern 162. For example, the dam pattern 168 may have the same material configuration as that of the channel stud pattern 162.

The insulating liner 160 may be formed on the side surface and the lower surface of the dam pattern 168. For example, the insulating liner 160 may extend conformally along at least a part of the side surface of the dam pattern 168 and the profile of the lower surface of the dam pattern 168 (e.g., along a bottom surface of the dam pattern 168).

The insulating liner 160 may include, for example, but is not limited to, at least one of silicon oxide, silicon nitride, and/or silicon oxynitride. As an example, the insulating liner 160 may include a silicon oxide film.

As shown in FIG. 6A, the dam pattern 168 may include a third via pattern 168a, and a third stud pattern 168b on the third via pattern 168a. The third via pattern 168a may extend long in the first direction Z, and penetrate the first insulating film 142a. For example, a third via hole VHc that extends in the first direction Z and penetrates the first insulating film 142a may be formed. The third via pattern 168a may fill a part of the third via hole VHc. The third stud pattern 168b may penetrate the second insulating film 142b and the third insulating film 142c, and be connected to the upper portion of the third via pattern 168a. For example, a third stud hole SHc, which extends in the first direction Z and exposes the upper surface of the third via pattern 168a, may be formed inside the second insulating film 142b and the third insulating film 142c. The third stud pattern 168b may be formed inside the third stud hole SHc and connected to the third via pattern 168a. In some implementations, the third via pattern 168a and the third stud pattern 168b may be formed integrally at the same level.

The insulating liner 160 and the third via pattern 168a may be stacked sequentially inside the third via hole VHc. For example, the insulating liner 160 may extend conformally along the profiles of the side surface and the lower surface of the third via hole VHc. The third via pattern 168a may fill at least a part of the region of the third via hole VHc that remains after the insulating liner 160 is filled. The insulating liner 160 may extend along the side surface and the lower surface of the third via pattern 168a. The insulating liner 160 may be interposed between the first insulating film 142a and the third via pattern 168a, and between the first insulating film 142a and the third via pattern 168a.

The insulating liner 160 may not be formed inside the third stud hole SHc. The insulating liner 160 may not extend along the side surface of the third stud pattern 168b. The insulating liner 160 may not be interposed between the second insulating film 142b and the third stud pattern 168b, and between the third insulating film 142c and the third stud pattern 168b.

In some implementations, the width of the third stud pattern 168b may be greater than the width of the third via pattern 168a. For example, in a plane including the lowermost surface of the third stud hole SHc, a width W3a of the third stud pattern 168b may be greater than a width W3b of the third via pattern 168a.

Although the width W3b of the third via pattern 168a is shown as being equal to the width W1b of the first via pattern 164a and/or the width W2b of the second via pattern 166a, this is an example. In some implementations, the width W3b of the third via pattern 168a may be different from the width W1b of the first via pattern 164a and/or the width W2b of the second via pattern 166a.

Although the width W3a of the third stud pattern 168b is shown as being smaller than the width W1a of the first stud pattern 164b and/or the width W2a of the second stud pattern 166b, this is an example. In some implementations, the width W3a of the third stud pattern 168b may be greater than or equal to the width W1a of the first stud pattern 164b and/or the width W2a of the second stud pattern 166b.

In some implementations, the height of the lowermost surface of the third stud pattern 168b may be lower than the height of the uppermost surface of the channel structure CH. For example, the depth DT3 at which the third stud pattern 168b is formed may be greater than the sum of the thicknesses of the second insulating film 142b and the thicknesses of the third insulating film 142c, on the basis of the upper surface of the third stud pattern 168b.

In some implementations, the third stud pattern 168b may cover the upper surface of the insulating liner 160. For example, in a plane including the lowermost surface of the third stud hole SHc, the width W3a of the third stud pattern 168b may be greater than the width of the third via hole VHc.

The first conductive structure 180 may be formed on the second interlayer insulating film 142. The first conductive structure 180 may provide an electrical path for the operation of each memory cell. For example, a first inter-wiring insulating film 144 may be formed on the second interlayer insulating film 142. The first conductive structure 180 may be formed inside the first inter-wiring insulating film 144, and be electrically connected to the channel stud pattern 162, the gate contact 172, the source contact 174, the first through via pattern 164, the second through via pattern 166, and/or the dam pattern 168. The shape, number of layers, disposition and the like of the first conductive structure 180 are examples, and the scope of this disclosure is not limited to those shown in the drawings.

The first conductive structure 180 may include a conductive material, for example, but is not limited to, at least one of aluminum (Al), copper (Cu), tungsten (W), molybdenum (Mo), cobalt (Co), ruthenium (Ru), and alloys thereof. As an example, the first conductive structure 180 may include copper (Cu) wiring.

In some implementations, the first through via pattern 164 may be electrically connected to the channel stud pattern 162, the gate contact 172, and/or the source contact 174 through the first conductive structure 180.

In some implementations, the first conductive structure 180 may include a conductive line 185 formed on the cell array region CA. The conductive line 185 may extend long in the third direction Y. The conductive line 185 may be commonly connected to a plurality of channel structures CH arranged along the third direction Y through the channel stud pattern 162. The plurality of conductive lines 185 may be spaced apart from each other in the second direction X. The conductive line 185 may be provided as a bit line (e.g., BL of FIG. 2) of the semiconductor memory device.

The conductive pad 390 may be formed on the external region PA. The conductive pad 390 may be formed on the first inter-wiring insulating film 144. The conductive pad 390 may be connected to the second through via pattern 166. For example, a first via plug 382 that connects the first conductive structure 180 and the conductive pad 390 may be formed inside the first inter-wiring insulating film 144. The second through via pattern 166 may be electrically connected to the conductive pad 390 through the first conductive structure 180 and the first via plug 382.

In some implementations, the second through via pattern 166 may form an input/output circuit. For example, the conductive pad 390 may be provided as an input/output pad of the semiconductor memory device.

In some implementations, the second through via pattern 166 may form an input/output circuit of the semiconductor memory device. For example, the conductive pad 390 may be provided as an input/output pad of the semiconductor memory device.

In some implementations, the second through via pattern 166 may form a crack detection circuit (CDC) of the semiconductor memory device. For example, the conductive pad 390 may be provided as the crack detection pad of the semiconductor memory device.

The peripheral circuit structure PERI may include a second substrate 200, a peripheral circuit element PT, and a second conductive structure 260.

The second substrate 200 may include, for example, a semiconductor substrate such as a silicon substrate, a germanium substrate or a silicon-germanium substrate. Alternatively, the second substrate 200 may include a silicon-on-insulator (SOI) substrate, a germanium-on-insulator (GOI) substrate, or the like.

The peripheral circuit element PT may be formed on the second substrate 200. The peripheral circuit element PT may constitute, form, include, or be included in a peripheral circuit (e.g., 30 of FIG. 1) that controls the operation of the semiconductor memory device. For example, the peripheral circuit element PT may include a control logic (e.g., 37 of FIG. 1), a row decoder (e.g., 33 of FIG. 1), a page buffer (e.g., 35 of FIG. 1) and the like. In the following description, a surface (e.g., the upper surface) of the second substrate 200 on which the peripheral circuit elements PT are disposed may also be referred to as a front side of the second substrate 200. Conversely, a surface (e.g., the lower surface) of the second substrate 200 opposite to the front side of the second substrate 200 may also be referred to as a back side of the second substrate 200.

The peripheral circuit element PT may include, for example, but is not limited to, a transistor. For example, the peripheral circuit element PT may include various passive elements such as a capacitor, a resistor, and an inductor as well as various active elements such as a transistor.

The second conductive structure 260 may be formed on the peripheral circuit elements PT. For example, a second inter-wiring insulating film 244 may be formed on the front side of the second substrate 200. The second conductive structure 260 may be formed inside the second inter-wiring insulating film 244 and be electrically connected to the peripheral circuit elements PT. The shape, number of layers, disposition and the like of the second conductive structure 260 are examples, and the scope of this disclosure is not limited to those shown in the drawings.

The second conductive structure 260 may include a conductive material, for example, but is not limited to, at least one of aluminum (Al), copper (Cu), tungsten (W), molybdenum (Mo), cobalt (Co), ruthenium (Ru), or alloys thereof. As an example, the second conductive structure 260 may include a copper (Cu) wiring.

In some implementations, the memory cell structure CELL may be stacked on the peripheral circuit structure PERI along the first direction Z. For example, the memory cell structure CELL may be stacked on the upper surface of the second inter-wiring insulating film 244.

In some implementations, the back side of the first substrate 100 may be opposite to the front side of the second substrate 200. For example, the first substrate 100 and/or the insulating substrate 101 may be stacked on the upper surface of the second inter-wiring insulating film 240.

In some implementations, the gate contact 172 may penetrate the insulating substrate 101, and be electrically connected to the second conductive structure 260. For example, the second conductive structure 260 may include a pad pattern 265. The pad pattern 265 may be, but is not limited to, the uppermost metal layer of the second conductive structure 260. The gate contact 172 may penetrate the insulating substrate 101 on the extension region EA, and be connected to the upper surface of the pad pattern 265. Accordingly, each of the gate electrodes 112 and 117 of the memory cell structure CELL may be electrically connected to the peripheral circuit structure PERI.

Each of the first through via pattern 164 and the second through via pattern 166 may be electrically connected to the second conductive structure 260. For example, each of the first through via pattern 164 and the second through via pattern 166 may penetrate the insulating substrate 101 on the external region PA, and be connected to the upper surface of the pad pattern 265. The first conductive structure 180 and the second conductive structure 260 may be electrically connected through the first through via pattern 164 and the second through via pattern 166. Accordingly, each memory cell and/or conductive pad 390 of the memory cell structure CELL may be electrically connected to the peripheral circuit structure PERI.

The insulating liner 160 may come into contact with the second conductive structure 260. For example, the insulating liner 160 may penetrate the insulating substrate 101 on the external region PA, and come into contact with the upper surface of the pad pattern 265. The dam pattern 168 may be spaced apart from the second conductive structure 260 by the insulating liner 160. For example, the insulating liner 160 on the lower surface of the dam pattern 168 may be interposed between the pad pattern 265 and the dam pattern 168. Thus, the pad pattern 265 and the dam pattern 168 may be physically and electrically separated (e.g., may be insulated from one another).

Referring to FIGS. 1 to 5 and 6B, in some implementations, the insulating liner 160 may be formed of multiple films.

For example, the insulating liner 160 may include a first liner film 160a and a second liner film 160b that are sequentially stacked inside the third via hole VHc. The first liner film 160a and the second liner film 160b may include different materials from each other. As an example, the first liner film 160a may include a silicon oxide film, and the second liner film 160b may include a silicon nitride film.

Referring to FIGS. 1 to 5 and 6C, in some implementations, the height of the uppermost portion of the insulating liner 160 may be higher than the height of the lowermost surface of the third stud pattern 168b.

For example, the uppermost portion of the insulating liner 160 may protrude above the lowermost surface of the third stud hole SHc. This may be due to the characteristics of the etching process for forming the third stud hole SHc. In some implementations, the upper surface of the insulating liner 160 may include a convex surface 160S1 that is convex toward the third stud pattern 168b.

Referring to FIGS. 1 to 5 and 6D, in some implementations, the height of the uppermost portion of the insulating liner 160 may be lower than the height of the lowermost surface of the third stud pattern 168b.

For example, the uppermost portion of the insulating liner 160 may be spaced apart from the lowermost surface of the third stud hole SHc. This may be due to the characteristics of the etching process for forming the third stud hole SHc. In some implementations, the upper surface of the insulating liner 160 may include a concave surface 160S2 that is concave toward the third stud pattern 168b.

Referring to FIGS. 1 to 5, 6E and 6F, in some implementations, each of the depth DT1 of the first stud pattern 164b and the depth DT2 of the second stud pattern 166b may be different from the depth DT3 of the third stud pattern 168b.

For example, as shown in FIG. 6E, each of the depth DT1 of the first stud pattern 164b and the depth DT2 of the second stud pattern 166b may be smaller than the depth DT3 of the third stud pattern 168b. In some implementations, each of the depth DT1 of the first stud pattern 164b and the depth DT2 of the second stud pattern 166b may be greater than the thickness of the third insulating film 142c, and smaller than the sum of the thickness of the second insulating film 142b and the thickness of the third insulating film 142c.

As another example, as shown in FIG. 6F, each of the depth DT1 of the first stud pattern 164b and the depth DT2 of the second stud pattern 166b may be greater than the depth DT3 of the third stud pattern 168b.

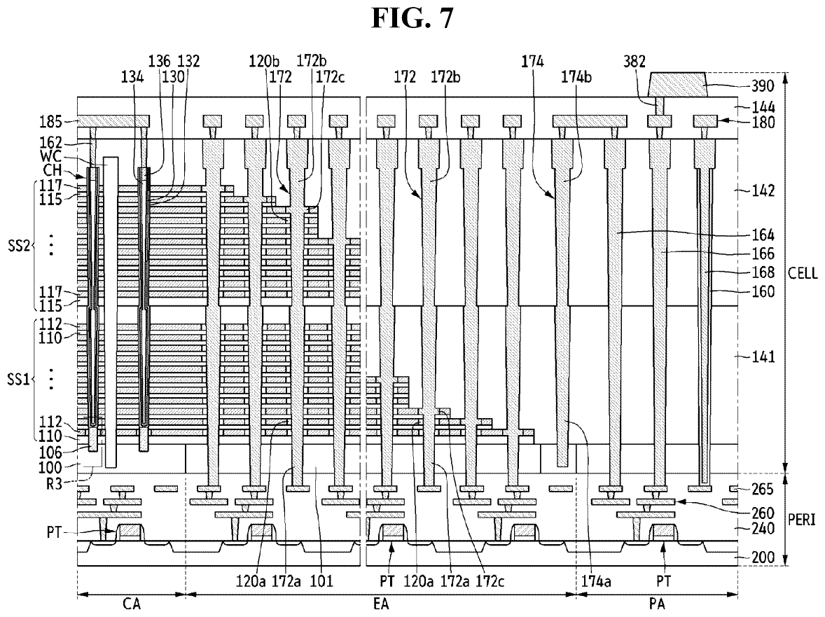

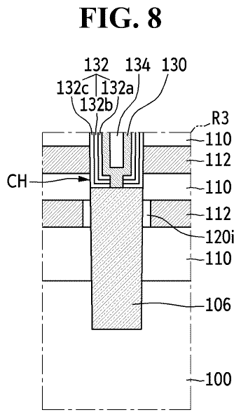

FIG. 7 is another schematic cross-sectional view taken along A-A of FIG. 3, illustrating another example of a semiconductor memory device. FIG. 8 is an enlarged view illustrating a region R3 of FIG. 7. For convenience of explanation, repeated parts of contents explained above using FIGS. 1 to 6F will be briefly explained or omitted, and differences will be mainly described. Otherwise, the semiconductor memory device of FIG. 7 is substantially similar to that of FIGS. 1 to 6F.

Referring to FIGS. 7 and 8, in some implementations, a semiconductor memory device includes a source pattern 106. The source pattern 106 may be formed on the first substrate 100. The source pattern 106 may be connected to the semiconductor film 130. For example, one end (e.g., an upper end) of the semiconductor film 130 may be connected to the channel pad 136, and the other end (e.g., a lower end) of the semiconductor film 130 may penetrate the data storage film 132 and come into contact with the source pattern 106.

The source pattern 106 may include a conductive material, for example, but is not limited to, impurity-doped polysilicon or metal. The source pattern 106 may be formed, for example, but is not limited to, by a selective epitaxial growth process from the first substrate 100. The source pattern 106 and/or the first substrate 100 may be provided as a common source line (e.g., CSL of FIG. 2) of the semiconductor memory device.

In some implementations, the source pattern 106 may intersect some of the first gate electrodes 112. As an example, the upper surface of the source pattern 106 may be formed to be higher than the upper surface of the lowermost electrode among the first gate electrodes 112. The lowermost electrode intersecting the source pattern 106 may be spaced apart from the source pattern 106 by a gate insulating film 120i that surrounds the side surface of the source pattern 106.

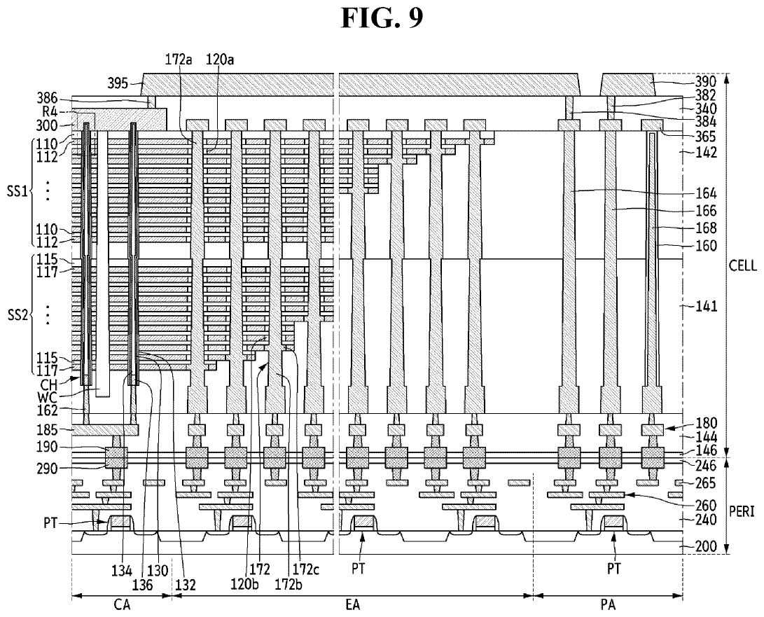

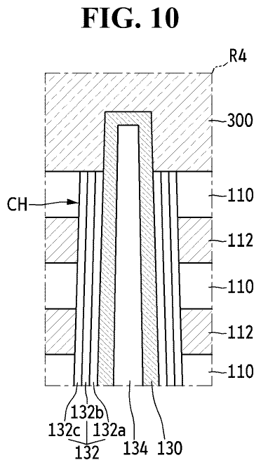

FIG. 9 is another schematic cross-sectional view taken along A-A of FIG. 3, illustrating another example of a semiconductor memory device. FIG. 10 is an enlarged view illustrating a region R4 of FIG. 9. For convenience of explanation, repeated parts of contents explained above using FIGS. 1 to 6F will be briefly explained or omitted, and differences will be mainly described. Otherwise, the semiconductor memory device of FIG. 9 is substantially similar to that of FIGS. 1 to 6F.

Referring to FIG. 9 and FIG. 10, in some implementations, a semiconductor memory device has a C2C (chip to chip) structure. The C2C structure may mean a structure in which an upper chip including a memory cell structure CELL is fabricated on a first wafer, and a lower chip including a peripheral circuit structure PERI is fabricated on a second wafer different from the first wafer, and then, the upper chip and the lower chip are connected to each other by a bonding method.

As an example, the bonding method may be a method of connecting a first bonding metal 190 (and/or the first bonding insulating film 146) formed on the uppermost metal layer of the upper chip and a second bonding metal 290 (and/or the second bonding insulating film 246) formed on the uppermost metal layer of the lower chip to each other. For example, when the first bonding metal 190 and the second bonding metal 290 are formed of copper (Cu), the bonding method may be a Cu—Cu bonding method. However, this is merely an example, and the first bonding metal 190 and the second bonding metal 290 may, of course, be formed of various other metals such as aluminum (Al) or tungsten (W).

As the first bonding metal 190 and the second bonding metal 290 are bonded, the first conductive structure 180 may be electrically connected to the second conductive structure 260. Accordingly, each memory cell and/or conductive pad 390 of the memory cell structure CELL may be electrically connected to the peripheral circuit structure PERI.

In some implementations, a source plate 300 may be formed on the first stacked structure SS1. The stacked structures SS1 and SS2 may be interposed between the peripheral circuit structure PERI and the source plate 300. The source plate 300 may be connected to the semiconductor film 130. For example, one end (e.g., a lower end) of the semiconductor film 130 may be connected to the channel pad 136, and the other end (e.g., an upper end) of the semiconductor film 130 may penetrate the data storage film 132, and come into contact with the source plate 300.

The source plate 300 may include a conductive material, for example, but is not limited to, impurity-doped polysilicon, metal or metal silicide. The source plate 300 may be provided as a common source line (e.g., CSL of FIG. 2) of the semiconductor memory device.

In some implementations, the other end (e.g., an upper end) of the semiconductor film 130 may protrude above the uppermost surface of the data storage film 132 and/or the uppermost surface of the first stacked structure SS1.

In some implementations, a back insulating film 340 and a third conductive structure 365 may be formed on the first stacked structure SS1 and/or the first interlayer insulating film 141. The stacked structures SS1 and SS2 may be interposed between the peripheral circuit structure PERI and the third conductive structure 365. The shape, number of layers, disposition and the like of the third conductive structure 365 are examples, and the scope of this disclosure is not limited to those shown in the drawings.

The third conductive structure 365 may include a conductive material, for example, but is not limited to, at least one of aluminum (Al), copper (Cu), tungsten (W), molybdenum (Mo), cobalt (Co), ruthenium (Ru), or alloys thereof.

In some implementations, the gate contact 172 may penetrate the stacked structures SS1 and SS2, and be electrically connected to the third conductive structure 365.

Each of the first through via pattern 164 and the second through via pattern 166 may be electrically connected to the third conductive structure 365. For example, each of the first through via pattern 164 and the second through via pattern 166 may be connected to the lower surface of the third conductive structure 365 on the external region PA. The first conductive structure 180 and the third conductive structure 365 may be electrically connected to each other through the first through via pattern 164 and the second through via pattern 166.

In some implementations, the first through via pattern 164 may be electrically connected to the source plate 300. For example, a connection pattern 395 may be formed on the back insulating film 340. In addition, a second via plug 384 that connects the third conductive structure 365 and the connection pattern 395, and a third via plug 386 that connects the source plate 300 and the connection pattern 395 may be formed inside the back insulating film 340. The first through via pattern 164 may be electrically connected to the source plate 300 through the third conductive structure 365, the second via plug 384, the connection pattern 395, and the third via plug 386.

The conductive pad 390 may be connected to the second through via pattern 166. For example, a first via plug 382 that connects the third conductive structure 365 and the conductive pad 390 may be formed inside the back insulating film 340. The second through via pattern 166 may be electrically connected to the conductive pad 390 through the third conductive structure 365 and the first via plug 382.

The insulating liner 160 may come into contact with the third conductive structure 365. For example, the insulating liner 160 may come into contact with the lower surface of the third conductive structure 365 on the external region PA. The dam pattern 168 may be spaced apart from the third conductive structure 365 by the insulating liner 160. For example, the insulating liner 160 on the upper surface of the dam pattern 168 may be interposed between the third conductive structure 365 and the dam pattern 168. Accordingly, the third conductive structure 365 and the dam pattern 168 may be physically and electrically separated from each other (e.g., insulated from one another).

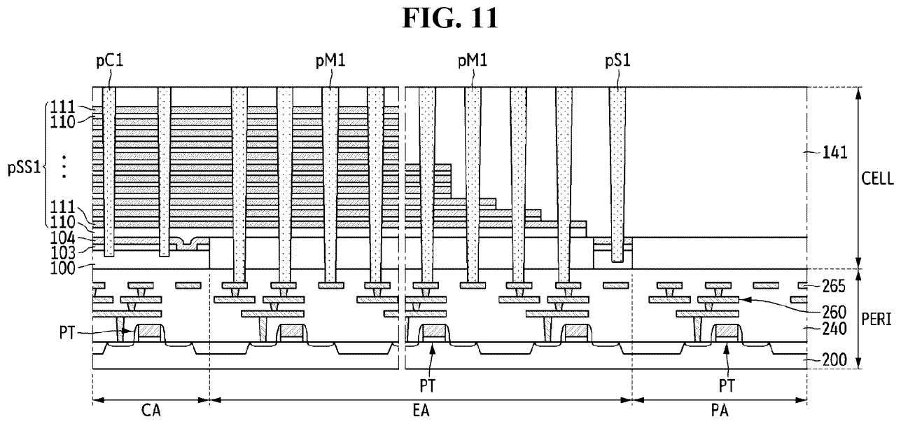

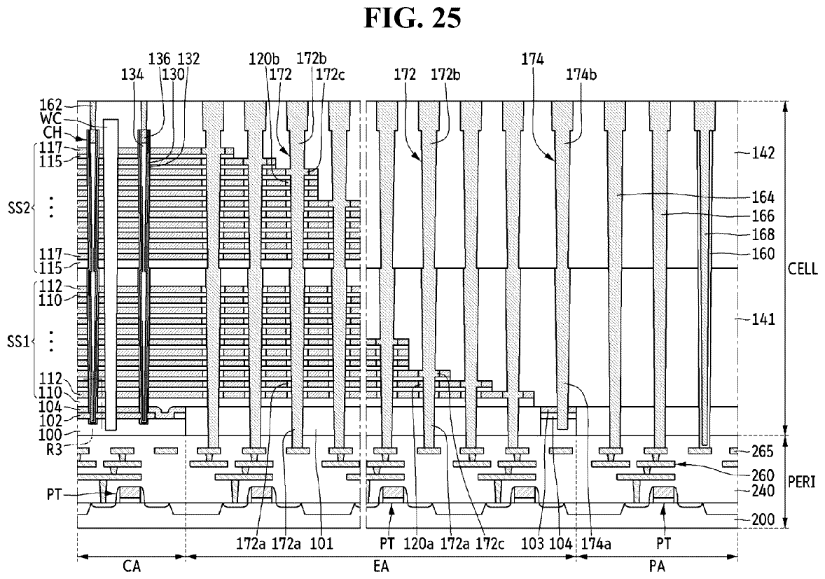

Hereinafter, an example of a method for fabricating a semiconductor memory device will be described referring to FIGS. 11 to 25. FIGS. 11 to 25 are intermediate step diagrams. For convenience of explanation, repeated parts of the contents explained above using FIGS. 1 to 10 will be briefly explained or omitted.

Referring to FIG. 11, a first mold structure pSS1, a first interlayer insulating film 141, a first preliminary channel pC1, a first preliminary gate contact pM1 and a first preliminary source contact pS1 are formed on the first substrate 100 and/or the insulating substrate 101.

The first mold structure pSS1 may be formed on the front side of the first substrate 100. The first mold structure pSS1 may include a plurality of first mold insulating films 110 and a plurality of first mold sacrificial films 111 that are stacked alternately on the first substrate 100. The first mold structure pSS1 on the extension region EA may be patterned in a stepped shape.

The first mold sacrificial films 111 may include a material having an etching selectivity with respect to the first mold insulating film 110. As an example, each of the first mold insulating films 110 may include a silicon oxide film, and each of the first mold sacrificial films 111 may include a silicon nitride film.

The first substrate 100 and/or the insulating substrate 101 may be stacked on the peripheral circuit structure PERI. For example, the peripheral circuit element PT, the second conductive structure 260, and the second inter-wiring insulating film 240 may be formed on the second substrate 200. The first substrate 100 and/or the insulating substrate 101 may be stacked on the second inter-wiring insulating film 240.

In some implementations, the source sacrificial layer 103 and the support layer 104 may be formed on the first substrate 100 before forming the first mold structure pSS1. The source sacrificial layer 103 may include a material having an etching selectivity with respect to the first mold insulating film 110. The support layer 104 may include a material having an etching selectivity with respect to the source sacrificial layer 103. As an example, the source sacrificial layer 103 may include a silicon nitride film, and the support layer 104 may include a polysilicon film.

The first interlayer insulating film 141 may cover the first substrate 100, the insulating substrate 101, and the first mold structure pSS1.

The first preliminary channel pC1 may be formed on the cell array region CA of the first substrate 100. The first preliminary channel pC1 may extend in the first direction Z and penetrate the first interlayer insulating film 141 and the stacked structures SS1 and SS2. The first preliminary channel pC1 may include a material having an etching selectivity with respect to the first mold insulating films 110 and the first mold sacrificial films 111. As an example, the first preliminary channel pC1 may include a polysilicon film.

The first preliminary gate contact pM1 may be formed on the extension region EA. The plurality of first preliminary gate contacts pM1 may be connected to the corresponding plurality of first mold sacrificial films 111. In some implementations, the first preliminary gate contact pM1 may extend in the first direction Z and penetrate the first interlayer insulating film 141 and the stacked structures SS1 and SS2. The first preliminary gate contact pM1 may include a material having an etching selectivity with respect to the first mold insulating films 110 and the first mold sacrificial films 111. As an example, the first preliminary gate contact pM1 may include a polysilicon film.

The first preliminary source contact pS1 may be formed on the extension region EA. The first preliminary source contact pS1 may penetrate the first interlayer insulating film 141, and be connected to the source sacrificial layer 103. The first preliminary source contact pS1 may include a material having an etching selectivity with respect to the first mold insulating films 110 and the first mold sacrificial films 111. As an example, the first preliminary source contact pS1 may include a polysilicon film.

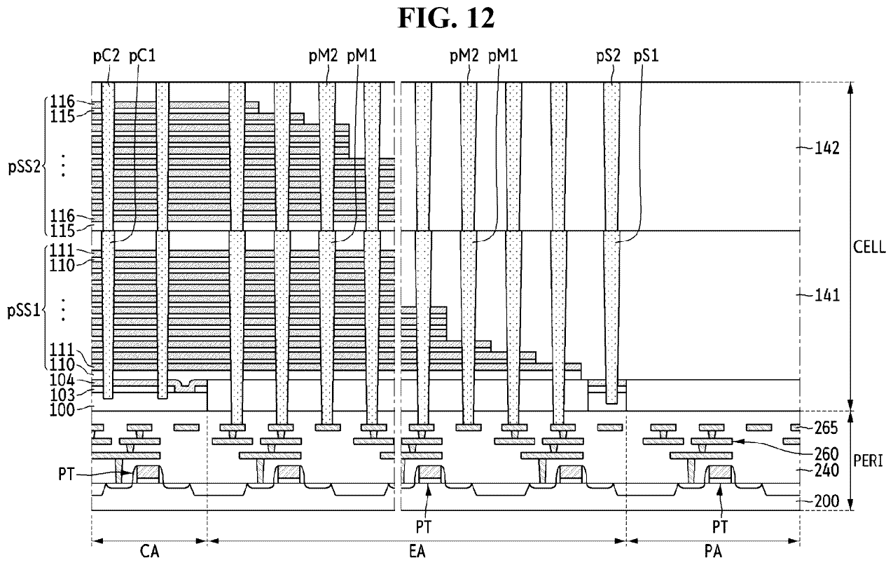

Referring to FIG. 12, a second mold structure pSS2, a second interlayer insulating film 142, a second preliminary channel pC2, a second preliminary gate contact pM2, and a second preliminary source contact pS2 are formed.

The second mold structure pSS2 may be formed on the first interlayer insulating film 141. The second mold structure pSS2 may include a plurality of second mold insulating films 115 and a plurality of second mold sacrificial films 116 that are stacked alternately on the first interlayer insulating film 141. The second mold structure pSS2 on the extension region EA may be patterned in a stepped shape. The second mold structure pSS2 may be similar to the first mold structure pSS1, and therefore a detailed description thereof will not be provided below.

The second interlayer insulating film 142 may cover the first interlayer insulating film 141 and the second mold structure pSS2.

The second preliminary channel pC2 may be connected to the first preliminary channel pC1. The second preliminary channel pC2 may be similar to the first preliminary channel pC1, and therefore a detailed description thereof will not be provided below.

The second preliminary gate contact pM2 may be connected to the first preliminary gate contact pM1. The second preliminary gate contact pM2 may be similar to the first preliminary gate contact pM1, and therefore a detailed description thereof will not be provided below.

The second preliminary source contact pS2 may be connected to the first preliminary source contact pS1. The second preliminary source contact pS2 may be similar to the first preliminary source contact pS1, and therefore the detailed description will not be provided below.

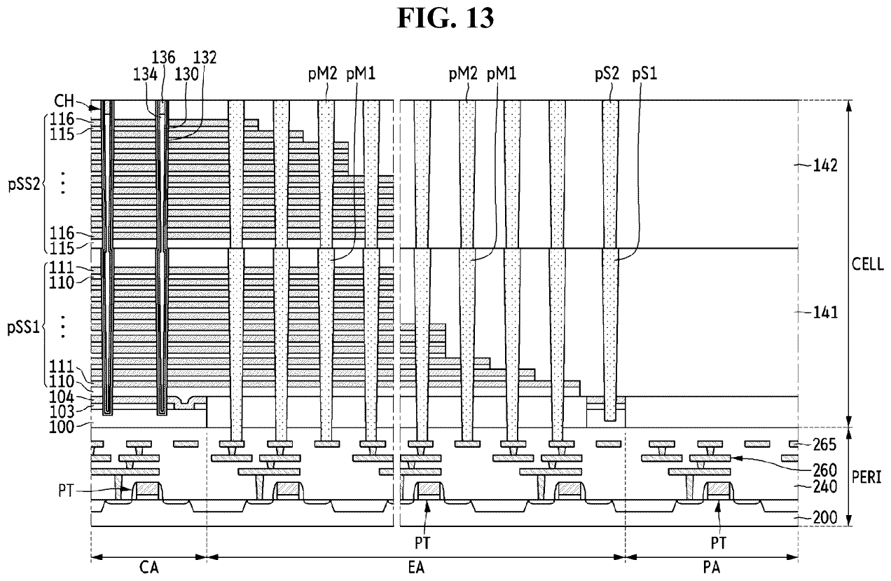

Referring to FIG. 13, the channel structure CH is formed.

For example, the first preliminary channel pC1 and the second preliminary channel pC2 may be selectively removed. Next, the data storage film 132, the semiconductor film 130, the filling insulating film 134, and the channel pad 136 may be formed sequentially inside the region from which the first preliminary channel pC1 and the second preliminary channel pC2 are removed. As a result, the channel structure CH that penetrates the first mold structure pSS1 and the second mold structure pSS2 may be formed.

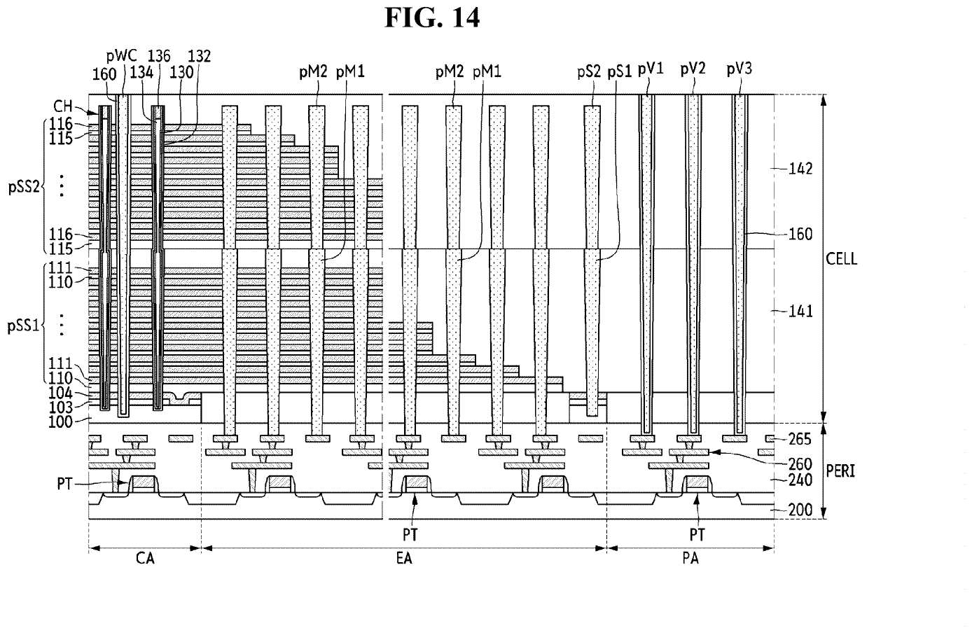

Referring to FIG. 14, an insulating liner 160, a cut sacrificial film pWC, a first sacrificial film pV1, a second sacrificial film pV2, and a third sacrificial film pV3 are formed.

The cut sacrificial film pWC may be formed on the cell array region CA and the extension region EA. The cut sacrificial film pWC may extend long in the second direction X and cut the stacked structures SS1 and SS2.

Each of the first sacrificial film pV1, the second sacrificial film pV2, and the third sacrificial film pV3 may be formed on the external region PA. Each of the first sacrificial film pV1, the second sacrificial film pV2, and the third sacrificial film pV3 may extend in the first direction Z and penetrate the first interlayer insulating film 141 and the second interlayer insulating film 142.

Each of the cut sacrificial film pWC, the first sacrificial film pV1, the second sacrificial film pV2, and the third sacrificial film pV3 may include a material having an etching selectivity with respect to the first mold structure pSS1, the second mold structure pSS2, the first interlayer insulating film 141, and the second interlayer insulating film 142. As an example, each of the cut sacrificial film pWC, the first sacrificial film pV1, the second sacrificial film pV2, and the third sacrificial film pV3 may include, but are not limited to, an amorphous carbon layer (ACL).

In some implementations, the cut sacrificial film pWC, the first sacrificial film pV1, the second sacrificial film pV2, and the third sacrificial film pV3 may be formed at the same level. For example, the cut sacrificial film pWC, the first sacrificial film pV1, the second sacrificial film pV2, and the third sacrificial film pV3 may be formed simultaneously by the same etching and/or deposition process.

The insulating liner 160 may be stacked (or deposited) before the cut sacrificial film pWC, the first sacrificial film pV1, the second sacrificial film pV2, and the third sacrificial film pV3 are formed. For example, the insulating liner 160 may extend conformally along the profile of the side surfaces and the lower surfaces of each of the cut sacrificial film pWC, the first sacrificial film pV1, the second sacrificial film pV2, and the third sacrificial film pV3.

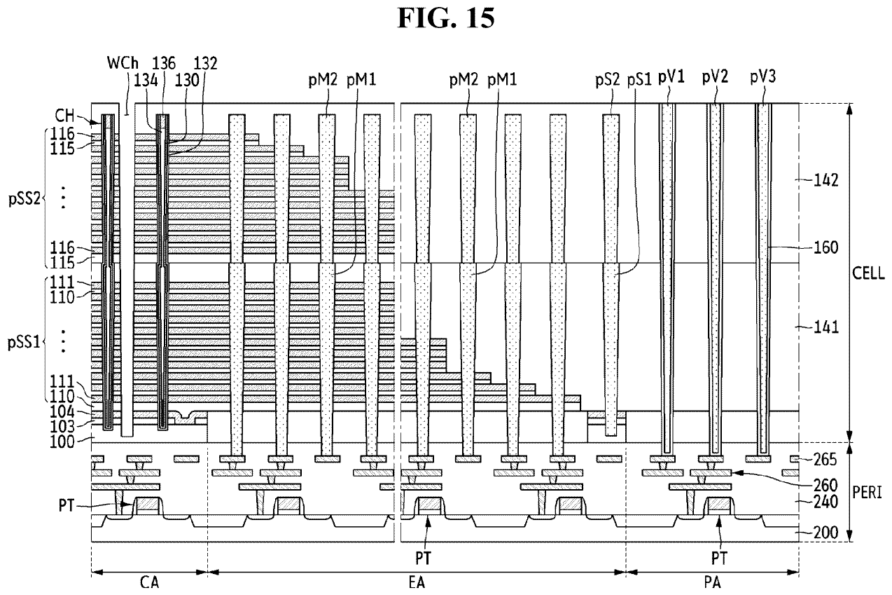

Referring to FIG. 15, the cut sacrificial film pWC is selectively removed.

As the cut sacrificial film pWC is removed, a cut region WCh which cuts the stacked structures SS1 and SS2 may be formed. After the cut sacrificial film pWC is removed, a part of the insulating liner 160 exposed from the cut region WCh may be removed.

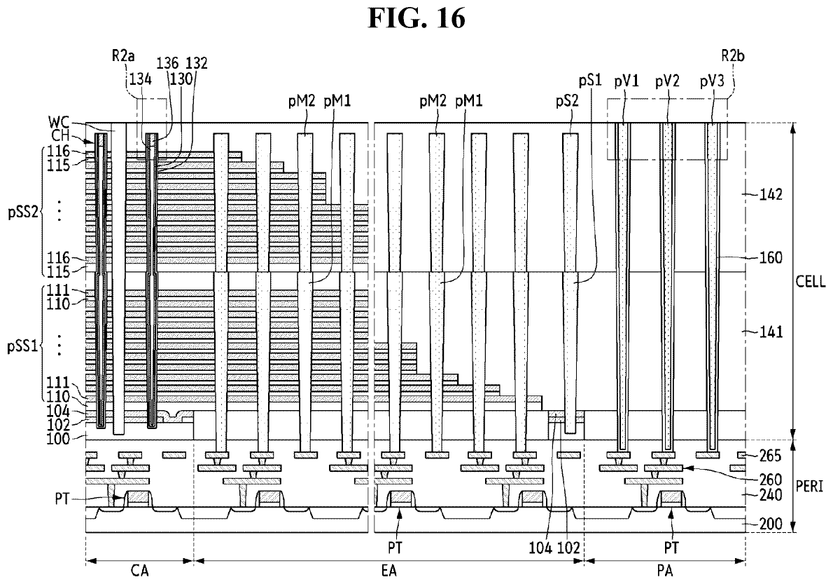

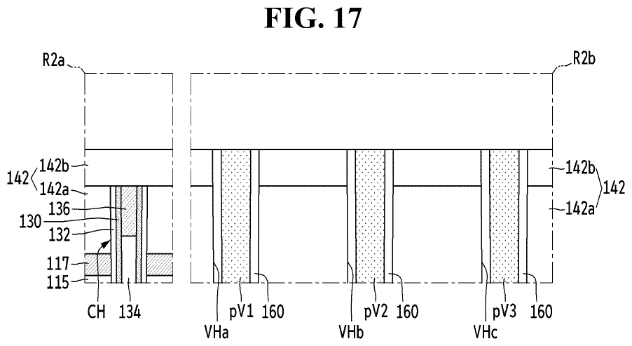

Referring to FIGS. 16 and 17, a source layer 102 and a plurality of gate electrodes 112 and 117 are formed. For reference, FIG. 17 is an enlarged view illustrating regions R2a and R2b of FIG. 16.

For example, a part of the source sacrificial layer 103 exposed by the cut region WCh may be selectively removed. Next, a source layer 102, which replaces the region from which the source sacrificial layer 103 is removed, may be formed. The source layer 102 may penetrate the data storage film 132 and come into contact with the side surface of the semiconductor film 130.

For example, the mold sacrificial films 111 and 116 exposed by the cut region WCh may be selectively removed. Next, gate electrodes 112 and 117, which replaces the region from which the mold sacrificial films 111 and 116 are removed, may be formed. Accordingly, the stacked structures SS1 and SS2 including the mold insulating films 110 and 115 and the gate electrodes 112 and 117 may be formed.

In some implementations, after the source layer 102 and the stacked structures SS1 and SS2 are formed, the cut region WCh may be filled with an insulating material. Accordingly, the cut pattern WC including an insulating material may be formed.

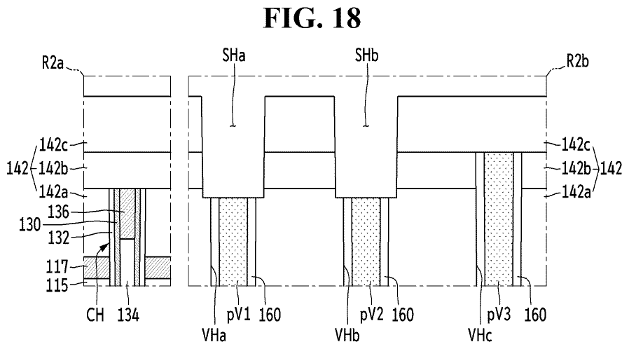

Referring to FIG. 18, a first stud hole SHa and a second stud hole SHb are formed.

The first stud hole SHa may penetrate the second insulating film 142b and the third insulating film 142c and expose the first sacrificial film pV1. The second stud hole SHb may penetrate the second insulating film 142b and the third insulating film 142c and expose the second sacrificial film pV2.

In some implementations, the first stud hole SHa and the second stud hole SHb may be formed at the same level. For example, the first stud hole SHa and the second stud hole SHb may be formed simultaneously by the same etching process.

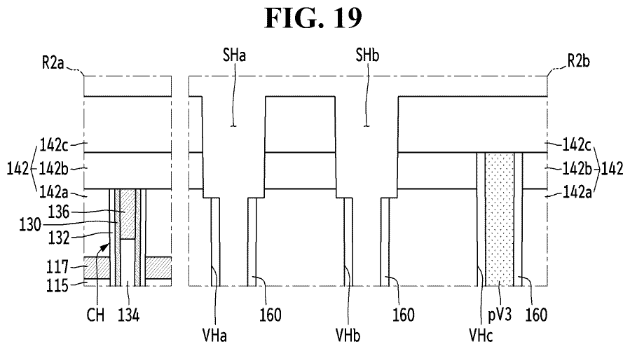

Referring to FIGS. 18 and 19, the first sacrificial film pV1 exposed by the first stud hole SHa and the second sacrificial film pV2 exposed by the second stud hole SHb are removed.

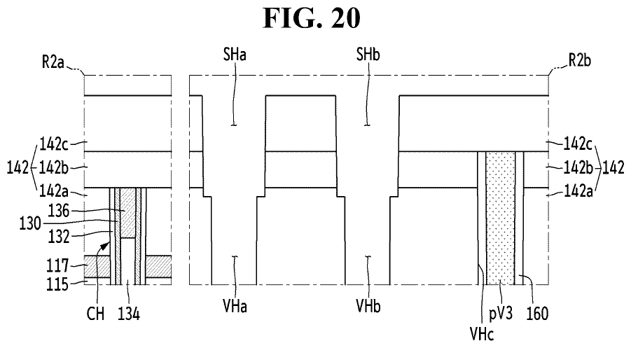

Referring to FIGS. 19 and 20, the insulating liner 160 in the first via hole VHa and the insulating liner 160 in the second via hole VHb are removed.

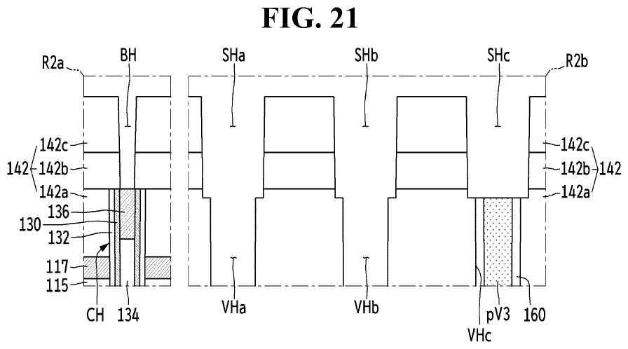

Referring to FIG. 21, a channel stud hole BH and a third stud hole SHc are formed.

For example, the sacrificial films pV1, pV2 and the insulating liner 160 in the first and second via holes VHa, VHb can be removed by etching through the first stud hole SHa and the second stud hole SHb.

The channel stud hole BH may penetrate the second insulating film 142b and the third insulating film 142c and expose the upper surface of the channel pad 136. The third stud hole SHc may penetrate the second insulating film 142b and the third insulating film 142c and expose the third sacrificial film pV3.

In some implementations, the channel stud hole BH and the third stud hole SHc may be formed at the same level. For example, the channel stud hole BH and the third stud hole SHc may be formed simultaneously by the same etching process.

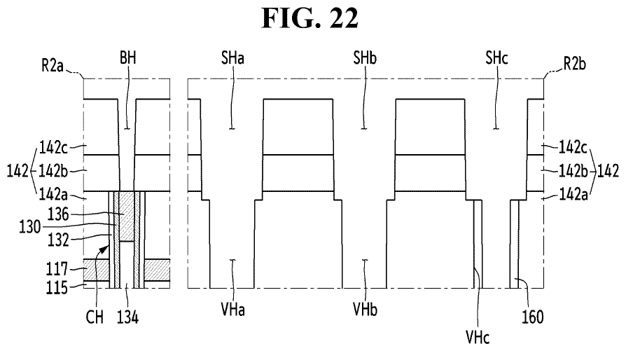

Referring to FIG. 22, the third sacrificial film pV3 exposed by the third stud hole SHc is removed. In some implementations, the insulating liner 160 inside the third via hole VHc may remain without being removed, e.g., remains after removal of the third sacrificial film pV3.

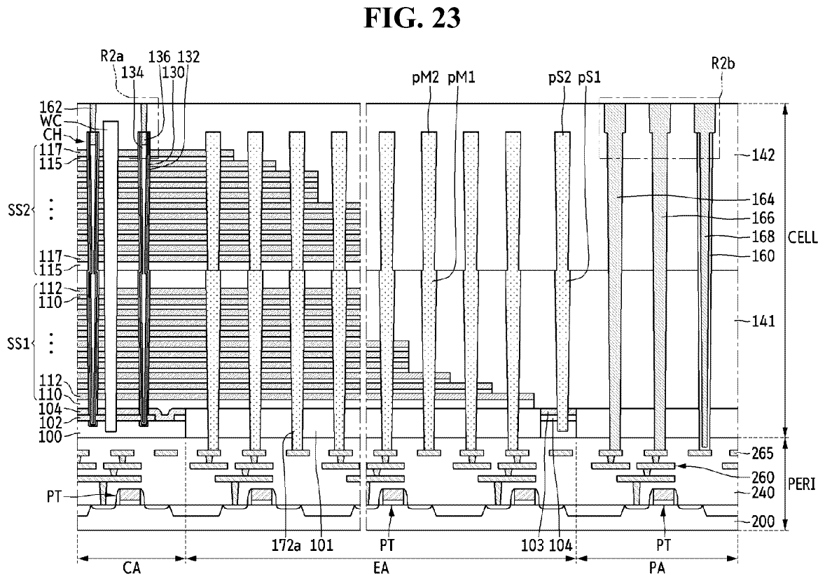

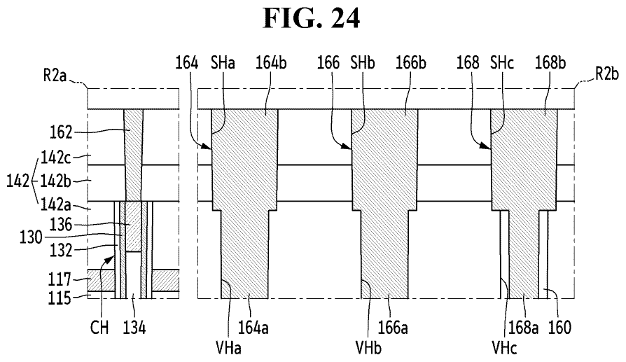

Referring to FIGS. 23 and 24, the channel stud pattern 162, the first through via pattern 164, the second through via pattern 166, and the dam pattern 168 are formed.

The channel stud pattern 162 may fill at least a part of the channel stud hole BH. The first through via pattern 164 may fill at least a part of the first via hole VHa and at least a part of the first stud hole SHa. The second through via pattern 166 may fill at least a part of the second via hole VHb and at least a part of the second stud hole SHb. The dam pattern 168 may fill at least a part of the third via hole VHc and at least a part of the third stud hole SHc.

Referring to FIGS. 23 to 25, the gate contact 172 and the source contact 174 are formed.

The gate contact 172 may be connected to each of the gate electrodes 112 and 117 in place of the first and second preliminary gate contacts pM1 and pM2. The source contact 174 may be connected to the source layer 102 in place of the first and second preliminary source contacts pS1 and pS2.

Next, referring to FIG. 4, the first conductive structure 180 and the conductive pad 390 are formed. Accordingly, the semiconductor memory device explained in reference to FIGS. 1 to 4 may be fabricated.

In order to prevent chipping of the semiconductor memory device, a dam (or a guard ring) may be formed along the edge of the semiconductor memory device. In a so-called COP (Cell on Peri) structure in which the memory cell structure is stacked on a peripheral circuit structure, such a dam may be formed at the same level as the through via that connects the peripheral circuit structure and the memory cell structure. However, as the semiconductor memory devices continue to become highly integrated, defects due to the scale difference between the dam and the through via present problems for reliability and yield.

In contrast, according to some implementations of the present disclosure, the etching process for forming the dam pattern 168 may be performed at a different level from the etching process for forming the first through via pattern 164 and/or the second through via pattern 166. For example, as explained above, the third stud hole SHc may be formed after the first stud hole SHa and the second stud hole SHb are formed. In some implementations, the third stud hole SHc may be formed simultaneously with the channel stud hole BH. Accordingly, defects caused by a scale difference between the dam pattern 168 and the first through via pattern 164 and/or the second through via pattern 166 are reduced, and semiconductor memory devices can be fabricated more reliably and with higher yield.

Hereinafter, an example of an electronic system including a semiconductor memory device as described above will be described. The semiconductor memory device may be any of the semiconductor memory devices described with respect to FIGS. 1 to 25.

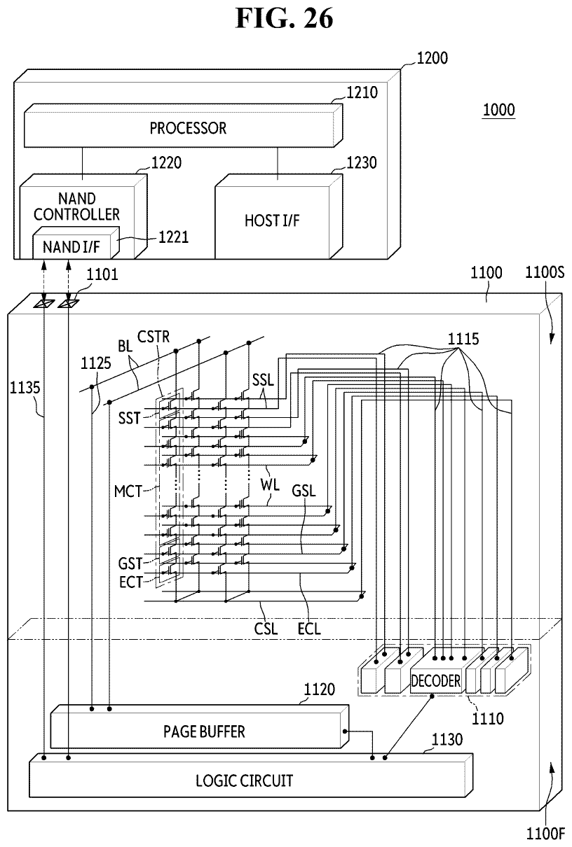

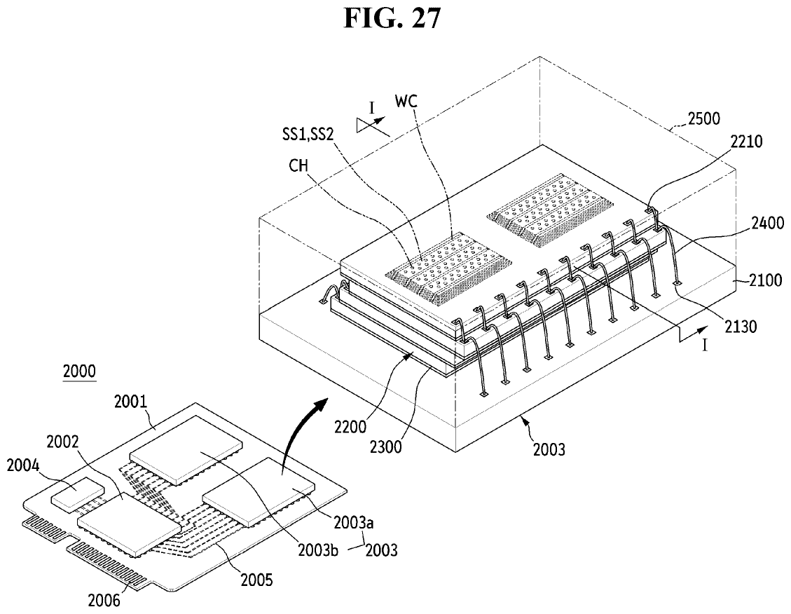

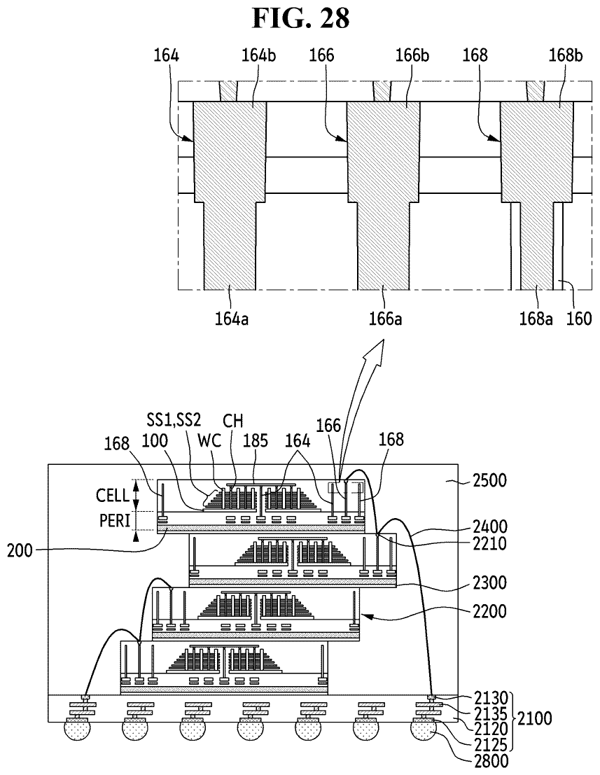

FIG. 26 is a block diagram illustrating an example of an electronic system. FIG. 27 is a perspective view illustrating an example of an electronic system. FIG. 28 is a schematic cross-sectional view taken along I-I of FIG. 27.

Referring to FIG. 26, an electronic system 1000 may include a semiconductor memory device 1100, and a controller 1200 that is electrically connected to the semiconductor memory device 1100. The electronic system 1000 may be a storage device that includes one or a plurality of semiconductor memory devices 1100, or an electronic device that includes the storage device. For example, the electronic system 1000 may be an SSD device (solid state drive device), a USB (Universal Serial Bus), a computing system, a medical device or a communication device that includes one or plurality of semiconductor memory devices 1100.

The semiconductor memory device 1100 may be a non-volatile memory device (e.g., a NAND flash memory device), and may be, for example, the semiconductor memory device explained above using FIGS. 1 to 10. The semiconductor memory device 1100 may include a first structure 1100F, and a second structure 1100S on the first structure 1100F.

The first structure 1100F may be a peripheral circuit structure that includes a decoder circuit 1110 (e.g., the row decoder 33 of FIG. 1), a page buffer 1120 (e.g., the page buffer 35 of FIG. 1), and a logic circuit 1130 (e.g., the control logic 37 of FIG. 1).

The second structure 1100S may include the common source line CSL, a plurality of bit lines BL, and a plurality of cell strings CSTR explained above using FIG. 2. The cell strings CSTR may be connected to the decoder circuit 1110 through the word line WL, at least one string selection line SSL, and at least one ground selection line GSL. In addition, the cell strings CSTR may be connected to the page buffer 1120 through the bit lines BL.

In some implementations, the common source line CSL and the cell strings CSTR may be electrically connected to the decoder circuit 1110 through first connection wirings 1115 extending from the first structure 1100F to the second structure 1100S. The first connection wiring 1115 may correspond to the first through via pattern 164 explained above using FIGS. 1 to 10.

In some implementations, the bit lines BL may be electrically connected to the page buffer 1120 through the second connection wirings 1125 extending from the first structure 1100F to the second structure 1100S. The second connection wiring 1125 may correspond to the first through via pattern 164 explained above using FIGS. 1 to 10.

The semiconductor memory device 1100 may communicate with the controller 1200 through an input/output pad 1101 electrically connected to the logic circuit 1130 (e.g., the control logic 37 of FIG. 1). The input/output pad 1101 may be electrically connected to the logic circuit 1130 through the input/output connection wiring 1135 extending from the inside of the first structure 1100F to the second structure 1100S. The input/output connection wiring 1135 may correspond to the second through via pattern 166 explained above using FIGS. 1 to 10.

The controller 1200 may include a processor 1210, a NAND controller 1220, and a host interface 1230. In some implementations, the electronic system 1000 may include a plurality of semiconductor memory devices 1100, and in this case, the controller 1200 may control the plurality of semiconductor memory devices 1100.

The processor 1210 may control the operation of the overall electronic system 1000 including the controller 1200. The processor 1210 may operate according to a predetermined firmware, and may control the NAND controller 1220 to access the semiconductor memory device 1100. The NAND controller 1220 may include a NAND interface 1221 that processes communication with the semiconductor memory device 1100. Control command for controlling the semiconductor memory device 1100, data to be recorded in the memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 27 and 28, the electronic system may include a main board 2001, a main controller 2002 mounted on the main board 2001, one or more semiconductor packages 2003, and a DRAM 2004. The semiconductor package 2003 and the DRAM 2004 may be connected to the main controller 2002 by wiring patterns 2005 formed on the main board 2001.

The main board 2001 may include a connector 2006 including a plurality of fins coupled to an external host. In the connector 2006, the number and disposition of the plurality of fins may vary depending on the communication interface between the electronic system 2000 and the external host. In some implementations, the electronic system 2000 may communicate with the external host according to any one of interfaces such as M-Phy for USB (Universal Serial Bus), PCI-Express (Peripheral Component Interconnect Express), SATA (Serial Advanced Technology Attachment), and UFS (Universal Flash Storage). In some implementations, the electronic system 2000 may operate by power supplied from the external host through the connector 2006. The electronic system 2000 may further include a PMIC (Power Management Integrated Circuit) that distributes the power supplied from the external host to the main controller 2002 and the semiconductor package 2003.

The main controller 2002 may record data in the semiconductor package 2003 or read data from the semiconductor package 2003, and may improve the operating speed of the electronic system 2000.

The DRAM 2004 may be a buffer memory for relieving a speed difference between the semiconductor package 2003, which is a data storage space, and the external host. The DRAM 2004 included in the electronic system 2000 may also operate as a kind of cache memory, and may also provide a space for temporarily storing data in the control operation on the semiconductor package 2003. When the DRAM 2004 is included in the electronic system 2000, the main controller 2002 may further include a DRAM controller for controlling the DRAM 2004, in addition to a NAND controller for controlling the semiconductor package 2003.

The semiconductor package 2003 may include a first semiconductor package 2003a and a second semiconductor package 2003b that are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on the lower surfaces of each of the package chips 220, a connecting structure 2400 for electrically connecting the semiconductor chips 2200 and the package substrate 2100, and a molding layer 2500 that covers the semiconductor chips 2200 and the connecting structure 2400 on the package substrate 2100.

The package substrate 2100 may be a printed circuit board that includes package upper pads 2130. Each semiconductor chip 2200 may include an input/output pad 2210. The input/output pad 2210 may correspond to the input/output pad 1101 of FIG. 26.

In some implementations, the connecting structure 2400 may be a bonding wire that electrically connects the input/output pad 2210 and the package upper pads 2130. Therefore, in each of the first semiconductor package 2003a and the second semiconductor package 2003b, the semiconductor chips 2200 may be electrically connected to each other by a bonding wire type, and may be electrically connected to the package upper pads 2130 of the package substrate 2100. In some implementations, in each of the first semiconductor package 2003a and the second semiconductor package 2003b, the semiconductor chips 2200 may be electrically connected to each other by a connecting structure including a through electrode (Through Silicon Via, TSV) instead of the connecting structure 2400 of the bonding wire type.

In some implementations, the main controller 2002 and the semiconductor chips 2200 may be included in a single package. In some implementations, the main controller 2002 and the semiconductor chips 2200 are mounted on a separate interposer substrate different from the main board 2001, and the main controller 2002 and the semiconductor chips 2200 may be connected to each other by the wiring formed on the interposer substrate.

In some implementations, the package substrate 2100 may be a printed circuit board. The package substrate 2100 may include a package substrate body portion 2120, package upper pads 2130 disposed on an upper surface of the package substrate body portion 2120, lower pads 2125 disposed on a lower surface of the package substrate body portion 2120 or exposed through the lower surface, and inner wirings 2135 that electrically connect the upper pads 2130 and the lower pads 2125 inside the package substrate body portion 2120. The upper pads 2130 may be electrically connected to the connecting structures 2400. The lower pads 2125 may be connected to the wiring patterns 2005 of the main board 2001 of the electronic system 2000 through conductive connections 2800, as in FIG. 27.

In the electronic system, each of the semiconductor chips 2200 may include the semiconductor memory device explained above using FIGS. 1 to 10. For example, each of the semiconductor chips 2200 may include a peripheral circuit structure PERI, and a memory cell structure CELL stacked on the peripheral circuit structure PERI. As an example, the peripheral circuit structure PERI may include the second substrate 200 explained above using FIGS. 1 to 6A. Further, as an example, the cell structure CELL may include the first substrate 100, the first stacked structure SS1, the second stacked structure SS2, the channel structure CH, the cut pattern WC, the first through via pattern 164, the second through via pattern 166, the dam pattern 168, the insulating liner 160, and the conductive line 185 as explained above using FIGS. 1 to 6A.

Although operations are shown in a specific order in the drawings, it should not be understood that the operations must be performed in the specific order or sequential order or that all of the operations must be performed, except where noted otherwise above. In certain situations, multitasking and parallel processing may be advantageous.

In concluding the detailed description, those skilled in the art will appreciate that many variations and modifications can be made to the above-described examples without departing from scope of the present disclosure.

1. A semiconductor memory device comprising:
a stacked structure comprising a plurality of gate electrodes spaced apart from each other in a first direction and stacked in the first direction;
a channel structure extending in the first direction, wherein the channel structure extends through the plurality of gate electrodes;
a dam pattern surrounding at least a portion of the stacked structure in a plan view along the first direction; and
an insulating liner extending along at least a portion of a side surface of the dam pattern and along a lower surface of the dam pattern.

2. The semiconductor memory device of claim 1,
wherein a height of an upper surface of the dam pattern is higher than a height of an uppermost one of the plurality of gate electrodes, and
wherein a height of the lower surface of the dam pattern is lower than a height of a lowermost one of the plurality of gate electrodes.

3. The semiconductor memory device of claim 1,
wherein the dam pattern includes a via pattern extending in the first direction, and a stud pattern on the via pattern,
wherein the insulating liner extends along a side surface of the via pattern and a lower surface of the via pattern, and
wherein the insulating liner is spaced apart from a side surface of a stud hole in which the stud pattern is formed.

4. The semiconductor memory device of claim 3, wherein a width of the stud pattern in a second direction intersecting the first direction is greater than a width of the via pattern in the second direction.

5. The semiconductor memory device of claim 3, wherein the stud pattern covers an upper surface of the insulating liner.

6. The semiconductor memory device of claim 1, further comprising:
a channel stud in contact with an upper surface of the channel structure,
wherein an upper surface of the dam pattern and an upper surface of the channel stud are disposed at a same level.

7. The semiconductor memory device of claim 1, further comprising:
a peripheral circuit structure disposed on a lower surface of the stacked structure,
wherein the peripheral circuit structure includes:
a peripheral circuit element, and
a conductive structure electrically connected to the peripheral circuit element.

8. The semiconductor memory device of claim 7, wherein the insulating liner separates the conductive structure from the dam pattern.

9. The semiconductor memory device of claim 7, further comprising:
a through via pattern spaced apart from the dam pattern in a second direction intersecting the first direction, wherein the through via pattern extends in the first direction, and
wherein the through via pattern is electrically connected to the conductive structure.

10. The semiconductor memory device of claim 9, wherein an upper surface of the dam pattern and an upper surface of the through via pattern are disposed at a same level.

11. A semiconductor memory device comprising:
a stacked structure comprising a plurality of gate electrodes spaced apart from each other in a first direction and stacked in the first direction;
a channel structure extending in the first direction, wherein the channel structure extends through and intersects the plurality of gate electrodes;
a first conductive structure on an upper surface of the stacked structure;
a second conductive structure on a lower surface of the stacked structure;
a through via pattern extending in the first direction, wherein the through via pattern electrically connects the first conductive structure and the second conductive structure;
a dam pattern surrounding at least a portion of a side surface of the stacked structure, wherein the dam pattern is vertically between the first conductive structure and the second conductive structure; and
an insulating liner extending along at least a portion of the dam pattern, wherein the insulating liner separates the second conductive structure from the dam pattern.

12. The semiconductor memory device of claim 11, wherein an upper surface of the through via pattern and an upper surface of the dam pattern are disposed at a same level.

13. The semiconductor memory device of claim 12, further comprising:
a channel stud in contact with an upper surface of the channel structure,
wherein the upper surface of the through via pattern, the upper surface of the dam pattern, and an upper surface of the channel stud are disposed at the same level.

14. The semiconductor memory device of claim 11, wherein a lower surface of the through via pattern and a lower surface of the insulating liner are disposed at a same level.

15. The semiconductor memory device of claim 11, wherein the through via pattern is between the stacked structure and the dam pattern along a second direction intersecting the first direction.

16. The semiconductor memory device of claim 11,
wherein the through via pattern includes:
a first via pattern extending in the first direction, and
a first stud pattern on the first via pattern, wherein a width of the first stud pattern in a second direction intersecting the first direction is different from a width of the first via pattern in the second direction, and
wherein the dam pattern includes:
a second via pattern extending in the first direction, and
a second stud pattern on the second via pattern, wherein a width of the second stud pattern in the second direction is different from a width of the second via pattern in the second direction.

17. The semiconductor memory device of claim 16,
wherein the insulating liner extends along a side surface of the second via pattern and along a lower surface of the second via pattern, and
wherein the insulating liner is spaced apart from a side surface of a stud hole in which the second stud pattern is formed.

18. The semiconductor memory device of claim 16, wherein a level of a lower surface of the first stud pattern and a level of a lower surface of the second stud pattern are different from each other.

19. The semiconductor memory device of claim 16,
wherein each of (i) a height of a lower surface of the first stud pattern and (ii) a height of a lower surface of the second stud pattern is lower than a height of an upper surface of the channel structure.

20.-25. (canceled)

26. An electronic system comprising:
a main board;
a semiconductor memory device on the main board; and
a controller on the main board, wherein the controller is electrically connected to the semiconductor memory device,
wherein the semiconductor memory device includes:
a stacked structure comprising a plurality of gate electrodes spaced apart from each other in a first direction and stacked in the first direction,
a channel structure extending in the first direction, wherein the channel structure extends through the plurality of gate electrodes,
a dam pattern surrounding at least a portion of the stacked structure in a plan view along the first direction, and
an insulating liner extending along at least portion of a side surface of the dam pattern and along a lower surface of the dam pattern.
